(19) United States
(12) Patent Application Publication
(10) Pub. No.: US 2026/0033271 A1
(43) Pub. Date: Jan. 29, 2026

(54) SUBSTRATE PROCESSING APPARATUS

(71) Applicant: SCREEN Holdings Co., Ltd., Kyoto (JP)

(72) Inventor: Hitoshi NAKAI, Kyoto-shi (JP)

(21) Appl. No.: 19/263,118

(22) Filed: Jul. 8, 2025

(30) Foreign Application Priority Data
Jul. 29, 2024 (JP) 2024-122046

(51) Int. Cl. H01L 21/67; H01L 21/687

(52) U.S. Cl. CPC H01L 21/67057; H01L 21/68742; H01L 21/68764

(57) ABSTRACT

A substrate processing apparatus includes a chamber, a substrate holding portion, and a moving mechanism. The chamber accommodates a substrate. The substrate holding portion is disposed in the chamber and holds the substrate one by one. The moving mechanism moves the substrate holding portion. The substrate holding portion includes a chuck pin that comes into contact with the substrate. The moving mechanism moves the substrate holding portion within the chamber between at least one processing position at which the substrate is processed with a processing liquid and a cleaning position at which the chuck pin is cleaned.

### CROSS REFERENCE TO RELATED APPLICATIONS

This application claims the benefit of priority to Japanese Patent Application No. 2024-122046 filed on Jul. 29, 2024. The entire contents of this application are hereby incorporated herein by reference.

### BACKGROUND OF THE INVENTION

### 1. Field of the Invention

The present invention relates to a substrate processing apparatus.

### 2. Description of Related Art

Conventionally, a substrate processing apparatus for processing a substrate is known. The substrate processing apparatus is suitably used for manufacturing a semiconductor substrate. The substrate processing apparatus processes a substrate by using a processing liquid such as a chemical liquid. As such a substrate processing apparatus, a single substrate processing type substrate processing apparatus that processes substrates one by one and a batch type substrate processing apparatus that processes a plurality of substrates by immersing the substrates in a processing bath at one time are known. For example, JP 2020-126886 A discloses a single substrate processing type substrate processing apparatus including a holding and rotating portion that holds and rotates a substrate, and an ejection portion that ejects a processing liquid to the substrate that is being rotated by the holding and rotating portion.

In a single substrate processing type substrate processing apparatus, substrates are processed one by one by supplying a processing liquid to a substrate while horizontally holding and rotating the substrate. In general, since a single substrate processing type substrate processing apparatus can be downsized compared with a batch type substrate processing apparatus, the consumption amount of a processing liquid can be reduced.

However, in the conventional single substrate processing type substrate processing apparatus, the holding and rotating portion that holds the substrate is provided at a processing position, and a contact portion of the holding and rotating portion that comes into contact with the substrate is not cleaned. Thus, the substrate may be contaminated with particles, etc., through the contact portion.

One of objects of the present invention is to provide a substrate processing apparatus capable of suppressing contamination of a substrate.

### SUMMARY OF THE INVENTION

According to one aspect of the present invention, a substrate processing apparatus includes a chamber, a substrate holding portion, and a moving mechanism. The chamber accommodates a substrate. The substrate holding portion is disposed in the chamber and holds the substrates one by one. The moving mechanism moves the substrate holding portion. The substrate holding portion includes a contact member that comes into contact with the substrate. The moving mechanism moves the substrate holding portion within the chamber between at least one processing position at which the substrate is processed with a processing liquid and a cleaning position at which the contact member is cleaned.

In a preferred embodiment, the substrate processing apparatus includes an immersion bath. The immersion bath is disposed at the processing position, stores the processing liquid, accommodates the substrate, and immerses the substrate in the processing liquid.

In a preferred embodiment, the immersion bath is provided with a support table that supports the substrate.

In a preferred embodiment, the substrate processing apparatus further includes a cleaning bath. The cleaning bath is disposed at the cleaning position, stores a cleaning liquid, and accommodates the contact member, and immerses the contact member in the cleaning liquid.

In a preferred embodiment, the substrate holding portion includes a rotation driving portion that rotates the contact member. The rotation driving portion rotates the contact member in a state in which the contact member is immersed in the cleaning liquid stored in the cleaning bath.

In a preferred embodiment, a plurality of the processing positions are provided. The moving mechanism moves the substrate holding portion between the plurality of processing positions.

In a preferred embodiment, the plurality of processing positions include a first processing position and a second processing position. The substrate is processed with a first processing liquid at the first processing position. The substrate is processed with a second processing liquid different from the first processing liquid at the second processing position.

In a preferred embodiment, the plurality of processing positions further include a third processing position. The processing liquid includes a first chemical liquid that is the first processing liquid, a second chemical liquid that is the second processing liquid, and a rinse liquid. The substrate is processed with the first chemical liquid at the first processing position. The substrate is processed with the second chemical liquid at the second processing position. The substrate is processed with the rinse liquid at the third processing position.

In a preferred embodiment, the processing liquid 5 includes a first chemical liquid that is the first processing liquid and a second chemical liquid that is the second processing liquid. The contact member is cleaned at the cleaning position after coming into contact with one of the first chemical liquid and the second chemical liquid and before coming into contact with the other of the first chemical liquid and the second chemical liquid.

In a preferred embodiment, the substrate holding portion transfers a plurality of the substrates one by one to the plurality of processing positions to process the plurality of substrates in parallel. The contact member is cleaned at the cleaning position before holding the substrate again.

In a preferred embodiment, the substrate processing apparatus includes a supporting member. The supporting member is disposed inside the chamber and supports the substrate. The chamber has an opening through which an inside and an outside of the chamber communicate with each other and the substrate is carried in and/or out. The inside of the chamber includes a support position at which the supporting member is disposed. The support position is located closer to the opening than the processing position. The substrate holding portion transfers the substrate from the support position to the processing positions.

In a preferred embodiment, the substrate holding portion horizontally holds the substrate. The substrate holding portion includes a base disposed above the substrate and a plurality of chuck pins protruding downward from the base and holding a circumferential edge of the substrate. The plurality of chuck pins are the contact member.

In a preferred embodiment, the moving mechanism includes a turning mechanism that turns the substrate holding portion about a turning axis. The processing position and the cleaning position are located on a circle centered on the turning axis. The turning mechanism moves the substrate holding portion between the processing position and the cleaning position in the chamber.

In a preferred embodiment, the chamber has an opening through which an inside and an outside of the chamber communicate with each other and the substrate is carried in and/or out. The cleaning position is farther from the opening than the processing position.

In a preferred embodiment, a plurality of the processing positions are provided. The plurality of processing positions and the cleaning position are located on a straight line. The moving mechanism moves the substrate holding portion within the chamber between the plurality of processing positions and the cleaning position by linearly moving the substrate holding portion.

In a preferred embodiment, the chamber has an opening through which an inside and an outside of the chamber communicate with each other and the substrate is carried in and/or out. The cleaning position is farther from the opening than the processing position.

In a preferred embodiment, a plurality of the processing positions are provided. The cleaning position is located between two of the processing positions. In a preferred embodiment, a plurality of the processing positions are provided. The processing liquid includes a chemical liquid and a rinse liquid. The plurality of processing positions include a chemical liquid processing position at which the substrate is processed with the chemical liquid and a rinse processing position at which the substrate is processed with the rinse liquid. The cleaning position is adjacent to the rinse processing position.

According to at least one aspect of the present invention, it is possible to provide a substrate processing apparatus capable of suppressing contamination of a substrate.

### BRIEF DESCRIPTION OF THE DRAWINGS

FIG. 1 is a schematic plan view of a substrate processing apparatus according to a first preferred embodiment.

FIG. 2 is a schematic plan view illustrating the inside of one chamber of the substrate processing apparatus according to the first preferred embodiment.

FIG. 3 is a block diagram of the substrate processing apparatus according to the first preferred embodiment.

FIG. 4 is a flowchart illustrating a substrate processing method according to the first preferred embodiment.

FIG. 5 is a schematic diagram of a substrate processing unit in the substrate processing apparatus according to the first preferred embodiment.

FIG. 6 is a schematic diagram illustrating a structure around a substrate holding portion and a moving mechanism of the substrate processing apparatus according to the first preferred embodiment.

FIG. 7 is a flowchart illustrating a method of immersing a substrate in a processing liquid.

FIG. 8 is a schematic diagram for describing a method of immersing a substrate in a processing liquid.

FIG. 9 is a schematic diagram for describing a method of immersing a substrate in a processing liquid.

FIG. 10 is a schematic diagram for describing a method of immersing a substrate in a processing liquid.

FIG. 11 is a schematic diagram illustrating a structure around a cleaning bath of the substrate processing apparatus.

FIG. 12 is a schematic plan view of a substrate processing apparatus according to a second preferred embodiment.

FIG. 13 is a schematic plan view illustrating the inside of one chamber of the substrate processing apparatus according to the second preferred embodiment.

FIG. 14 is a flowchart illustrating a substrate processing method according to the second preferred embodiment.

FIG. 15 is a schematic plan view of a substrate processing apparatus according to a third preferred embodiment.

FIG. 16 is a schematic diagram illustrating a structure around a substrate holding portion and a moving mechanism of the substrate processing apparatus according to the third preferred embodiment.

FIG. 17 is a schematic plan view of a substrate processing apparatus according to a fourth preferred embodiment.

FIG. 18 is a schematic plan view illustrating the inside of one chamber of the substrate processing apparatus according to the fourth preferred embodiment.

FIG. 19 is a flowchart illustrating a substrate processing method of the substrate processing apparatus according to a first modification example of the present invention.

FIG. 20 is a schematic plan view illustrating the inside of one chamber of a substrate processing apparatus according to a second modification example of the present invention.

FIG. 21 is a flowchart illustrating a substrate processing method of the substrate processing apparatus according to the second modification example.

FIG. 22 is a schematic plan view illustrating the inside of one chamber of a substrate processing apparatus according to a third modification example.

FIG. 23 is a flowchart illustrating a substrate processing method of the substrate processing apparatus according to the third modification example of the present invention.

FIG. 24 is a schematic plan view illustrating the inside of one chamber of a substrate processing apparatus according to a fourth modification example of the present invention.

### DETAILED DESCRIPTION OF PREFERRED EMBODIMENTS

Hereinafter, preferred embodiments of a substrate processing apparatus according to the present invention will be described with reference to the drawings. Note that in the drawings, the same or corresponding portions are denoted by the same reference numerals, and the description thereof will not be repeated. In the present specification, an X axis, a Y axis, and a Z axis orthogonal to each other may be described in order to facilitate understanding of the invention. In the present preferred embodiment, the X axis and the Y axis are parallel to the horizontal direction, and the Z axis is parallel to the vertical direction. For easy understanding, a processing liquid may be hatched in the drawings.

### First Preferred Embodiment

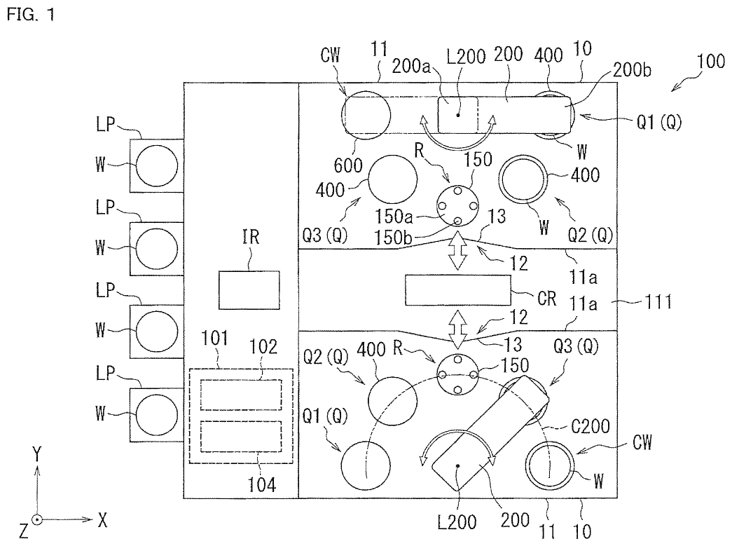

A substrate processing apparatus 100 according to a first preferred embodiment of the present invention will be described with reference to FIGS. 1 to 11. FIG. 1 is a schematic plan view of the substrate processing apparatus 100 according to the first preferred embodiment.

The substrate processing apparatus 100 processes a substrate W. The substrate processing apparatus 100 processes the substrate W to perform at least one of etching, surface processing, characteristics imparting, processing film formation, removal of at least a portion of the film, and cleaning on the substrate W.

The substrate W is used as a semiconductor substrate. The substrate W includes a semiconductor wafer. For example, the substrate W has a substantially disk shape. Here, the substrate processing apparatus 100 processes the substrates W one by one.

As illustrated in FIG. 1, the substrate processing apparatus 100 includes a plurality of substrate processing units 10, a plurality of load ports LP, an indexer robot IR, a center robot CR, a passage 111, a carry-in chamber 112, and a controller 101. The controller 101 controls the indexer robot IR and the center robot CR. The controller 101 includes a controlling portion 102 and a storage portion 104.

The substrate W is carried into the carry-in chamber 112 from the outside. Specifically, the carry-in chamber 112 has a substantially rectangular shape extending in a predetermined direction (here, the Y direction). A plurality of load ports LP are connected to the carry-in chamber 112. The indexer robot IR is disposed inside the carry-in chamber 112. The substrate W is carried from the load port LP into the carry-in chamber 112 by the indexer robot IR.

The passage 111 is connected to the carry-in chamber 112. The passage 111 has, for example, a substantially rectangular shape extending in a direction (here, the X direction) intersecting the extending direction of the carry-in chamber 112. The center robot CR is disposed inside the passage 111.

Each of the load ports LP stacks and accommodates a plurality of substrates W. The indexer robot IR transfers the substrate W between the load port LP and the center robot CR. The center robot CR transfers the substrate W between the indexer robot IR and the substrate processing unit 10. Each of the substrate processing units 10 ejects a processing liquid onto the substrate W to process the substrate W. The processing liquid includes, for example, a chemical liquid, a rinse liquid, a removing liquid, and/or a water repellent.

Specifically, the plurality of substrate processing units 10 form a plurality of towers disposed on both sides in the Y direction across a passage 111 through which the center robot CR passes in a plan view. Each tower includes a plurality of (for example, three) substrate processing units 10 stacked one above the other.

The substrate processing apparatus 100 includes a processing liquid cabinet (not illustrated) that supplies a processing liquid to all the substrate processing units 10 included in the substrate processing apparatus 100. The processing liquid cabinet has a pump, a nozzle, a filter and/or a tank to circulate the processing liquid.

The controller 101 controls various operations of the substrate processing apparatus 100. The controller 101 causes the substrate processing unit 10 to process the substrate W.

The controller 101 includes a controlling portion 102 and a storage portion 104. The controlling portion 102 includes a processor. The controlling portion 102 includes, for example, a central processing unit (CPU). Alternatively, the controlling portion 102 may include a general-purpose computing device.

The storage portion 104 stores data and a computer program. The data includes recipe data. The recipe data includes information indicating a plurality of recipes. Each of the plurality of recipes defines processing content and processing procedures of the substrate W. The controlling portion 102 executes the computer program stored in the storage portion 104 to execute a substrate processing operation.

The storage portion 104 includes a main storage device and an auxiliary storage device. The main storage device is, for example, a semiconductor memory. The auxiliary storage device is, for example, a semiconductor memory and/or a hard disk drive. The storage portion 104 may include a removable medium. The controlling portion 102 executes the computer program stored in the storage portion 104 to execute the substrate processing operation.

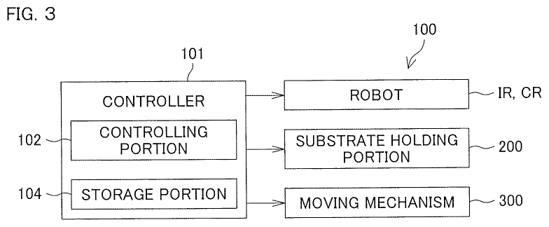

Subsequently, the substrate processing unit 10 will be described with reference to FIG. 1. As illustrated in FIG. 1, the substrate processing unit 10 includes a chamber 11, a substrate holding portion 200, a moving mechanism 300 (see FIG. 3), and an immersion bath 400.

The chamber 11 is connected to the passage 111. The chamber 11 extends, for example, along the passage 111.

The chamber 11 has a substantially box shape having an internal space. The chamber 11 accommodates the substrates W. Here, the substrate processing apparatus 100 is of a single substrate processing type of processing the substrates W one by one. The substrate W is accommodated in the chamber 11 and processed in the chamber 11. The chamber 11 accommodates the substrate holding portion 200, the moving mechanism 300 (see FIG. 3), and the immersion bath 400. The chamber 11 also has a side wall 11a that partitions the inside of the chamber 11 and the outside (here, the passage 111). An opening 12 through which the substrate W is carried in and out by the center robot CR is defined at a predetermined position of the side wall 11a. In the present preferred embodiment, one opening 12 is provided for one chamber 11. The opening 12 allows the inside of the chamber 11 and the passage 111 to communicate with each other and the substrate W to be taken in and out through the opening 12. A shutter 13 that opens and closes the opening 12 is provided at a predetermined position on the side wall 11a of the chamber 11. The same number of shutters 13 as the number of openings 12 are provided.

The substrate holding portion 200 holds the substrate W. Specifically, the substrate holding portion 200 holds the substrates W one by one. The substrate holding portion 200 horizontally holds the substrate W so that the upper surface (front surface) of the substrate W faces upward and the lower surface (rear surface) of the substrate W faces vertically downward. The substrate holding portion 200 rotates the substrate W while holding the substrate W. For example, a laminated structure in which a recess is formed is provided on the upper surface (front surface) of the substrate W. The detailed structure of the substrate holding portion 200 will be described later.

The moving mechanism 300 (see FIG. 3) moves the substrate holding portion 200. In the present preferred embodiment, the moving mechanism 300 turns the substrate holding portion 200. The moving mechanism 300 turns the substrate holding portion 200 about a turning axis L200 extending in the vertical direction. The turning axis L200 may be located inside or outside the substrate holding portion 200 in a plan view. In the present preferred embodiment, the substrate holding portion 200 has a substantially rectangular shape in a plan view having a basal end portion 200a and a distal end portion 200b. The turning axis L200 is located at the basal end portion 200a of the substrate holding portion 200. The distal end portion 200b of the substrate holding portion 200 is located above the substrate W and holds the substrate W.

In addition, the moving mechanism 300 moves the substrate holding portion 200 in the vertical direction. That is, the moving mechanism 300 lifts and lowers the substrate holding portion 200. The moving mechanism 300 includes, for example, a ball screw mechanism and an electric motor that applies a driving force to the ball screw mechanism. A detailed structure of the moving mechanism 300 will be described later.

In the substrate processing unit 10, there are one or more processing positions Q at which the substrate W is processed with a processing liquid. The processing positions Q are provided in the chamber 11. In the present preferred embodiment, a plurality of (here, three) processing positions Q are provided in each chamber 11.

For example, the substrate W is subjected to an immersion processing with the processing liquid at least at one of the plurality of processing positions Q. In the present preferred embodiment, the substrate W is subjected to the immersion processing with the processing liquid at each processing position Q. Specifically, the substrate processing unit 10 includes the immersion bath 400 disposed at each processing position Q. The immersion bath 400 stores a processing liquid in which the substrate W is immersed.

In addition, the substrate processing unit 10 has a cleaning position CW at which a chuck pin 202 of the substrate holding portion 200 that will be described later is cleaned. The cleaning position CW is provided in the chamber 11. In the present preferred embodiment, one cleaning position CW is provided in each chamber 11.

For example, at the cleaning position CW, the chuck pin 202 that will be described later is cleaned by a cleaning liquid. Specifically, the substrate processing unit 10 includes a cleaning bath 600 disposed at the cleaning position CW. The cleaning bath 600 stores a cleaning liquid in which a tip portion (lower portion) of the chuck pin 202 is immersed. The tip portion (lower portion) of the chuck pin 202 is a portion in contact with the substrate W. The cleaning liquid is, for example, a rinse liquid, which does not limit the cleaning liquid as long as the chuck pin 202 can be cleaned. In the present preferred embodiment, the cleaning liquid is deionized water (DIW).

In addition, the substrate processing unit 10 has a delivery position R. The delivery position R is provided in the chamber 11. In the present preferred embodiment, one delivery position R is provided in each chamber 11. The delivery position R is a position where the substrate W is delivered between the center robot CR and the substrate holding portion 200.

The delivery position R is disposed to face the opening 12. Specifically, the delivery position R is located closer to the opening 12 than the processing position Q and the cleaning position CW. The substrate W is carried into the delivery position R through the opening 12. The opening 12 is located between the center robot CR and the delivery position R in a state in which the center robot CR is disposed at a predetermined position (for example, the position illustrated in FIG. 1).

The substrate processing unit 10 includes a delivery table 150. The delivery table 150 is disposed at the delivery position R. The delivery table 150 is a table for delivering the substrate W between the center robot CR and the substrate holding portion 200. The delivery table 150 supports the substrate W. Note that the delivery table 150 is an example of a “supporting member” of the present invention.

Specifically, the delivery table 150 includes a circular plate 150a and a plurality of (here, four) projection portions 150b protruding upward from the plate 150a. The plurality of projection portions 150b support the lower surface Wb of the substrate W. The plurality of projection portions 150b are disposed, for example, at equal angular intervals (here, 90°) around the center of the plate 150a at the peripheral edge portion of the plate 150a.

The plurality of processing positions Q, the cleaning position CW, and the delivery position R are located on a circle C200 centered on the turning axis L200 of the substrate holding portion 200. That is, the distance from the turning axis L200 to the plurality of processing positions Q, the distance from the turning axis L200 to the cleaning position CW, and the distance from the turning axis L200 to the delivery position R are substantially equal. Therefore, by being turned about the turning axis L200, the substrate holding portion 200 can easily deliver the substrate W to and from, for example, a member at any processing position Q (here, the immersion bath 400), a member at the cleaning position CW (here, the cleaning bath 600), and a member at the delivery position R (here, the delivery table 150).

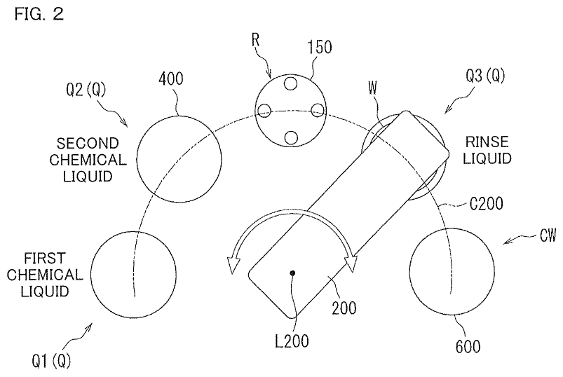

FIG. 2 is a schematic plan view illustrating the inside of one chamber 11 of the substrate processing apparatus 100 of the first preferred embodiment. As illustrated in FIG. 2, for example, in each chamber 11, a plurality of (here, three) processing positions Q include at least two processing positions Q to process the substrate W with different processing liquids. In the present preferred embodiment, in each chamber 11, the substrate W is processed with different processing liquids at all the three processing positions Q. Hereinafter, in order to facilitate understanding, the three processing positions Q may be referred to as a processing position Q1, a processing position Q2, and a processing position Q3. In the present preferred embodiment, the processing position Q1, the processing position Q2, and the processing position Q3 are disposed in order in the clockwise direction. In the present preferred embodiment, different processing liquids indicate that the liquids are not the same processing liquid. In the present preferred embodiment, the same processing liquid indicates that, for example, the types and components of the processing liquids are the same.

Specifically, the plurality of processing positions Q include a first processing position (for example, the processing position Q1) at which the substrate W is processed with a first chemical liquid, a second processing position (for example, the processing position Q2) at which the substrate W is processed with a second chemical liquid different from the first chemical liquid, and a third processing position (for example, the processing position Q3) at which the substrate W is processed with a rinse liquid.

The chemical liquid includes, for example, HF (hydrofluoric acid), DHF (dilute hydrofluoric acid), phosphoric acid, SPM (sulfuric acid/hydrogen peroxide water mixed solution), or ozone water, which does not limit the chemical liquid. The SPM is a sulfuric acid hydrogen peroxide water mixed solution in which a sulfuric acid and hydrogen peroxide water are mixed. In the present preferred embodiment, the first chemical liquid is a phosphoric acid. The second chemical liquid is a phosphoric acid having a concentration different from that of the first chemical liquid or dilute hydrofluoric acid (DHF). The chemical liquid may be, for example, SC1 (a mixed solution of ammonia water, hydrogen peroxide water, and water) or an organic solvent.

Examples of the rinse liquid include deionized water (DIW), carbonated water, electrolyzed ion water, ozone water, ammonia water, hydrochloric acid water having a dilution concentration (for example, about 10 ppm to 100 ppm), or reduced water (hydrogen water). In the present preferred embodiment, the rinse liquid is deionized water (DIW).

In the present preferred embodiment, the processing position Q1, the processing position Q2, the delivery position R, the processing position Q3, and the cleaning position CW are disposed in order from one side to the other side in the X direction. That is, the cleaning position CW and the cleaning bath 600 are disposed at positions farthest from the position (delivery position R) at which the substrate W is delivered to and from the center robot CR. In other words, among the delivery position R, the processing position Q, and the cleaning position CW, the cleaning position CW is located farthest from the opening 12. In the present preferred embodiment, the distance from the delivery position R to the cleaning position CW and the distance from the delivery position R to the processing position Q1 are the same.

Next, the substrate processing apparatus 100 according to the first preferred embodiment will be described with reference to FIG. 3. FIG. 3 is a block diagram of the substrate processing apparatus 100 according to the first preferred embodiment.

As illustrated in FIG. 3, the controller 101 controls various operations of the substrate processing apparatus 100. The controller 101 controls the indexer robot IR, the center robot CR, the substrate holding portion 200, and the moving mechanism 300. Specifically, the controller 101 controls the indexer robot IR, the center robot CR, the substrate holding portion 200, and the moving mechanism 300 by transmitting control signals to the indexer robot IR, the center robot CR, the substrate holding portion 200, and the moving mechanism 300.

The controlling portion 102 controls the indexer robot IR to deliver the substrate W by the indexer robot IR.

The controlling portion 102 controls the center robot CR to deliver the substrate W by the center robot CR. For example, the center robot CR receives the unprocessed substrate W and carries the substrate W into one of the plurality of chambers 11. In addition, the center robot CR receives the processed substrate W from the chamber 11 and carries out the substrate W.

The controlling portion 102 controls the substrate holding portion 200 to control attachment/detachment of the substrate W, start of rotation of the substrate W, change of a rotational speed, and stop of rotation of the substrate W. For example, the controlling portion 102 can control the substrate holding portion 200 to change a rotational speed of the substrate holding portion 200. Specifically, the controlling portion 102 can change a rotational speed of the substrate W by changing a rotational speed of an electric motor 204 that will be described later of the substrate holding portion 200.

The controlling portion 102 controls the moving mechanism 300 to change an angular position of the substrate holding portion 200 in the turning direction. For example, the controlling portion 102 controls the moving mechanism 300 to turn the substrate holding portion 200 about the turning axis L200, thereby moving the substrate holding portion 200 to the three processing positions Q, the cleaning position CW, and the delivery position R.

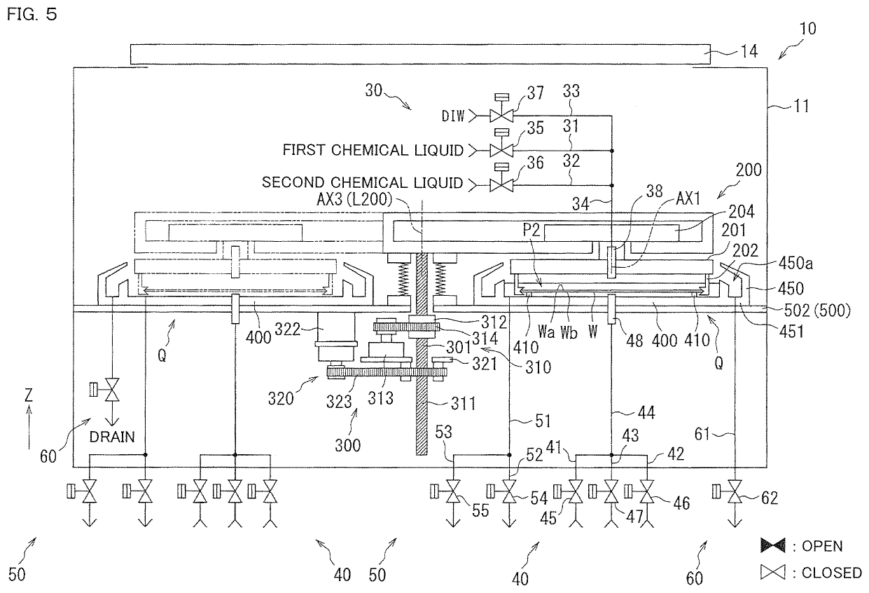

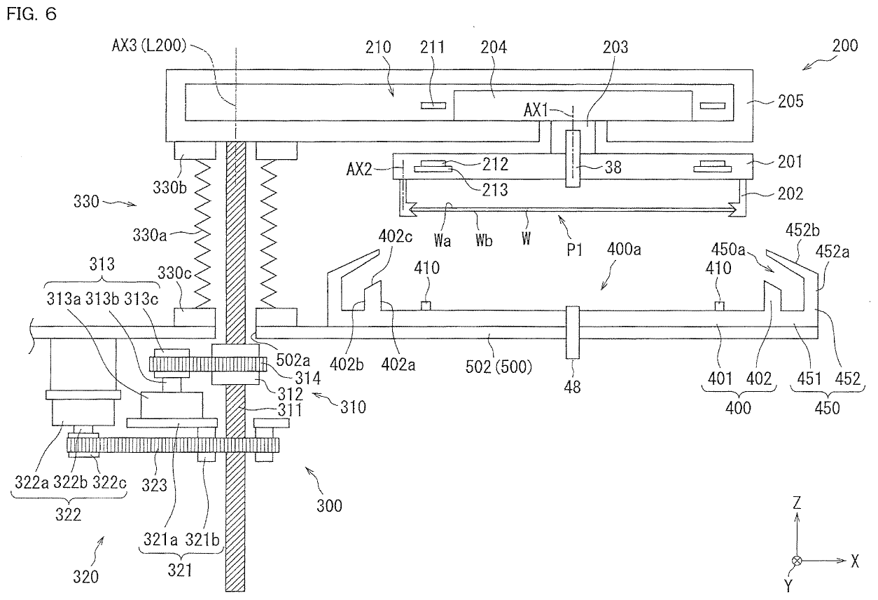

In addition, the controlling portion 102 controls the moving mechanism 300 to change a height position of the substrate holding portion 200. For example, the controlling portion 102 moves the substrate W between a first height position P1 (see FIG. 6) and a second height position P2 (see FIG. 5) by controlling the moving mechanism 300 to move the substrate holding portion 200. The first height position P1 is a height position of the substrate W when the substrate W is delivered between the center robot CR and the substrate holding portion 200. The second height position P2 is a height position of the substrate W when the substrate W is immersed in the processing liquid stored in the immersion bath 400. That is, the state in which the substrate W is disposed at the first height position P1 is a non-immersion state in which the substrate W is located outside the immersion bath 400. The state in which the substrate W is disposed at the second height position P2 is an immersion state in which the substrate W is located inside the immersion bath 400 and immersed in the processing liquid.

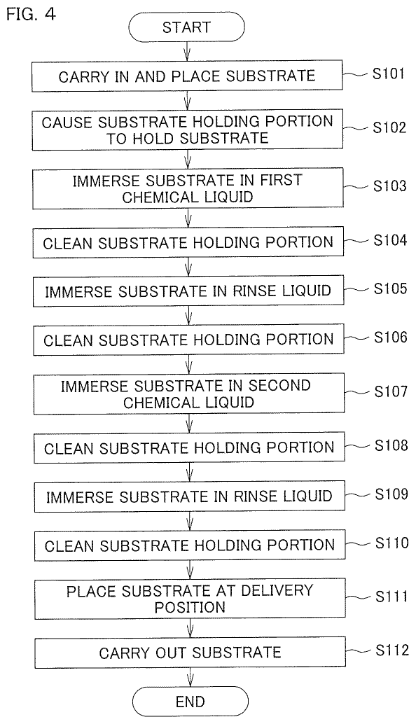

Next, a substrate processing method according to the first preferred embodiment will be described with reference to FIG. 4. FIG. 4 is a flowchart illustrating a substrate processing method according to the first preferred embodiment. The substrate processing method performed by the substrate processing apparatus 100 according to the first preferred embodiment includes steps S101 to S112. Steps S101 to S112 are executed by the controlling portion 102.

As illustrated in FIG. 4, in step S101, the substrate W is carried into the chamber 11. Specifically, the controlling portion 102 controls the center robot CR to carry the substrate W supported by the arm of the center robot CR into the chamber 11 and place the substrate W on the delivery table 150. Thereafter, the controlling portion 102 controls the center robot CR to retract the arm from the delivery position R. In this case, the substrate holding portion 200 is located at a position other than the delivery position R. In this case, the substrate W is carried into the chamber 11 through the opening 12.

Next, in step S102, the substrate W is held by the substrate holding portion 200. Specifically, the controlling portion 102 controls the moving mechanism 300 to turn the substrate holding portion 200 to the delivery position R. The controlling portion 102 controls the moving mechanism 300 and the substrate holding portion 200 to hold the substrate W by the substrate holding portion 200. Note that the substrate holding portion 200 may be cleaned in advance at the cleaning position CW prior to step S102.

Next, in step S103, the substrate W is processed with the first chemical liquid. Specifically, the controlling portion 102 controls the moving mechanism 300 to turn the substrate holding portion 200 to the processing position Q1. The controlling portion 102 controls the moving mechanism 300 to lower the substrate holding portion 200. As a result, the substrate W is immersed in the first chemical liquid stored in advance in the immersion bath 400. That is, the moving mechanism 300 immerses the substrate W in the first chemical liquid by moving (lowering) the substrate holding portion 200 in a state in which the first chemical liquid is stored in the immersion bath 400. In the present preferred embodiment, a predetermined amount of the first chemical liquid is stored in the immersion bath 400 before step S102 is executed.

In this case, in the present preferred embodiment, while the substrate holding portion 200 is rotating the substrate W, the moving mechanism 300 immerses the substrate W in the first chemical liquid stored in advance in the immersion bath 400.

The controlling portion 102 controls the substrate holding portion 200 to release the holding of the substrate W by the substrate holding portion 200. Thereafter, the controlling portion 102 controls the moving mechanism 300 to lift the substrate holding portion 200. In this case, the substrate W is immersed in the first chemical liquid.

Next, in step S104, the substrate holding portion 200 is cleaned at the cleaning position CW. Specifically, the controlling portion 102 controls the moving mechanism 300 to turn the substrate holding portion 200 by a predetermined angle. As a result, the substrate holding portion 200 is moved to the cleaning position CW.

The controlling portion 102 controls the moving mechanism 300 to lower the substrate holding portion 200. As a result, the tip portion (lower portion) of the chuck pin 202, which will be described later, of the substrate holding portion 200 is immersed in the cleaning liquid stored in advance in the cleaning bath 600. That is, the moving mechanism 300 moves (lowers) the substrate holding portion 200 in a state in which the cleaning liquid is stored in the cleaning bath 600, thereby immersing the chuck pin 202 that will be described later in the processing liquid. In the present preferred embodiment, a predetermined amount of the cleaning liquid is stored in the cleaning bath 600 before step S104 is executed.

Thereafter, when a predetermined time has elapsed from the start of the cleaning process on the substrate holding portion 200, the controlling portion 102 controls the moving mechanism 300 to lift the substrate holding portion 200.

Next, in step S105, the substrate W is processed with a rinse liquid. Specifically, the controlling portion 102 controls the moving mechanism 300 to turn the substrate holding portion 200 to the processing position Q1. When a predetermined time has elapsed from the start of the processing of the substrate W with the first chemical liquid in step S103, the controlling portion 102 controls the moving mechanism 300 and the substrate holding portion 200 to lower the substrate holding portion 200 such that the substrate W is held by the substrate holding portion 200. Thereafter, the controlling portion 102 controls the moving mechanism 300 to lift the substrate holding portion and turn the substrate holding portion 200 to the processing position Q3.

The controlling portion 102 controls the moving mechanism 300 to lower the substrate holding portion 200. As a result, the substrate W is immersed in the rinse liquid stored in advance in the immersion bath 400. That is, the moving mechanism 300 immerses the substrate W in the rinse liquid by moving (lowering) the substrate holding portion 200 in a state in which the rinse liquid is stored in the immersion bath 400. In the present preferred embodiment, a predetermined amount of the rinse liquid is stored in the immersion bath 400 before step S105 is executed.

Other immersion methods of the substrate W in step S105 are similar to those in step S103.

Next, in step S106, similarly to step S104, the substrate holding portion 200 is cleaned at the cleaning position CW.

Next, in step S107, the substrate W is processed with the second chemical liquid. Specifically, the controlling portion 102 controls the moving mechanism 300 to turn the substrate holding portion 200 to the processing position Q3. When a predetermined time has elapsed from the start of the processing of the substrate W with the rinse liquid in step S105, the controlling portion 102 controls the moving mechanism 300 and the substrate holding portion 200 to lower the substrate holding portion 200 such that the substrate W is held by the substrate holding portion 200. Thereafter, the controlling portion 102 controls the moving mechanism 300 to lift the substrate holding portion 200 and turn the substrate holding portion 200 to the processing position Q2.

The controlling portion 102 controls the moving mechanism 300 to lower the substrate holding portion 200. As a result, the substrate W is immersed in the second chemical liquid stored in advance in the immersion bath 400. That is, the moving mechanism 300 immerses the substrate W in the second chemical liquid by moving (lowering) the substrate holding portion 200 in a state in which the second chemical liquid is stored in the immersion bath 400. In the present preferred embodiment, a predetermined amount of the second chemical liquid is stored in the immersion bath 400 before step S107 is executed.

Other immersion methods of the substrate W in step S107 are similar to those in step S103.

Next, in step S108, similarly to step S104, the substrate holding portion 200 is cleaned at the cleaning position CW.

Next, in step S109, the substrate W is processed with a rinse liquid. Specifically, the controlling portion 102 controls the moving mechanism 300 to turn the substrate holding portion 200 to the processing position Q2. When a predetermined time has elapsed from the start of the processing of the substrate W with the second chemical liquid in step S107, the controlling portion 102 controls the moving mechanism 300 and the substrate holding portion 200 to lower the substrate holding portion 200 such that the substrate W is held by the substrate holding portion 200. Thereafter, the controlling portion 102 controls the moving mechanism 300 to lift the substrate holding portion and turn the substrate holding portion 200 to the processing position Q3.

The controlling portion 102 immerses the substrate W in the rinse liquid in the same manner as in step S105.

Next, in step S110, similarly to step S104, the substrate holding portion 200 is cleaned at the cleaning position CW.

Next, in step S111, the substrate W is placed on the delivery table 150. Specifically, the controlling portion 102 controls the moving mechanism 300 to turn the substrate holding portion 200 to the processing position Q3. When a predetermined time has elapsed from the start of the processing of the substrate W with the rinse liquid in step S109, the controlling portion 102 controls the moving mechanism 300 and the substrate holding portion 200 to lower the substrate holding portion 200 such that the substrate W is held by the substrate holding portion 200. Thereafter, the controlling portion 102 controls the moving mechanism 300 to lift the substrate holding portion 200 and turn the substrate holding portion 200 to the delivery position R.

The controlling portion 102 controls the moving mechanism 300 and the substrate holding portion 200 to lower the substrate holding portion 200 and place the substrate W on the delivery table 150. Thereafter, the controlling portion 102 controls the moving mechanism 300 to retract the substrate holding portion 200 from the delivery position R.

Next, in step S112, the substrate W is carried out of the chamber 11. Specifically, the controlling portion 102 controls the center robot CR to hold the substrate W placed on the delivery table 150 and carry the substrate W out of the chamber 11.

As described above, the processing on the substrate W ends. Note that the substrate holding portion 200 may also be cleaned at the cleaning position CW after step S112.

In the present preferred embodiment, as described above, the moving mechanism 300 moves the substrate holding portion 200 between the processing position Q at which the substrate W is processed with the processing liquid and the cleaning position CW at which the chuck pin 202 is cleaned in the chamber 11. Therefore, after the chuck pin 202 is cleaned at the cleaning position CW, the substrate W can be held by the chuck pin 202. Therefore, it is possible to suppress particles and/or a chemical liquid from adhering to the substrate W through the chuck pins 202. As a result, contamination of the substrate W can be suppressed.

As described above, the substrate processing apparatus 100 includes the immersion bath 400 that stores the processing liquid and in which the substrate W is immersed in the processing liquid. Therefore, when the substrate W is processed with the processing liquid, it is not necessary to continue to supply the processing liquid to the substrate W, and thus, it is possible to suppress an increase in the consumption amount of the processing liquid even when processing for a long time is required. In addition, since it is not necessary to continue to supply the processing liquid to the substrate W, for example, even in a case where a plurality of types of processing using the same processing liquid are performed in parallel in the plurality of chambers 11, it is possible to suppress timings of supplying the processing liquid from the processing liquid cabinet (not illustrated) from overlapping. Therefore, since it is possible to suppress an increase in the liquid feeding amount per unit time of the processing liquid cabinet, the processing liquid cabinet can be downsized.

In addition, since the substrates W are immersed one by one in the immersion bath 400 and processed, it is possible to suppress particles of other substrates W from adhering (transferring) to a certain substrate W.

As described above, the cleaning bath 600 in which the cleaning liquid is stored and the chuck pins 202 holding the substrate W are immersed in the cleaning liquid is provided. Therefore, particles and/or a chemical liquid, etc. adhering to the chuck pin 202 can be removed. Therefore, since the substrate W can be held by the clean chuck pins 202, contamination of the substrate W can be suppressed. In addition, for example, it is possible to suppress mixing of a plurality of chemical liquids in the immersion bath 400.

As described above, the moving mechanism 300 moves the substrate holding portion 200 between the plurality of processing positions Q. Therefore, for example, the number of the substrate holding portions 200 can be reduced compared with the case where the substrate holding portion is provided for each processing position Q. In addition, since the number of the substrate holding portions 200 can be reduced, it is possible to suppress an increase in size of the substrate processing apparatus 100.

In addition, there are a plurality of processing positions Q in one chamber 11. Therefore, it is possible to perform various types of processing compared with a case where there is only one processing position Q in one chamber 11. For example, as described above, one substrate W can be processed at a plurality of processing positions Q. Further, for example, as described later, it is also possible to process two substrates W in parallel.

As described above, the substrate W is processed with the first processing liquid (for example, the first chemical liquid) at the first processing position (for example, the processing position Q1), and the substrate W is processed with the second processing liquid (for example, the second chemical liquid) different from the first processing liquid at the second processing position (for example, the processing position Q2). Therefore, in one chamber 11, the substrate W can be processed with at least two processing liquids. For example, unlike a case where processing using the first chemical liquid and processing using the second processing liquid are performed at one processing position Q, processing can be performed in a state in which a processing liquid is stored in the immersion bath 400. In other words, it is not necessary to replace the processing liquid in the immersion bath 400 every time the substrate W is immersed. Therefore, the consumption of the processing liquid can be further reduced.

As described above, the substrate W is processed with the first chemical liquid at the first processing position (for example, the processing position Q1), the substrate W is processed with the second chemical liquid at the second processing position (for example, the processing position Q2), and the substrate W is processed with the rinse liquid at the third processing position (for example, the processing position Q3). Therefore, in one chamber 11, the substrates W can be processed with at least three processing liquids. Further, since the substrate W processing liquids. processed with the first chemical liquid and the substrate W processed with the second chemical liquid are rinsed at the same processing position Q3, it is possible to suppress an increase in the number of positions (for example, the processing position Q3) at which rinse processing is performed.

As described above, the chuck pin 202 is cleaned at the cleaning position CW after being in contact with the first chemical liquid and before being in contact with the second chemical liquid. Therefore, since the first chemical liquid adhering to the chuck pin 202 can be removed, it is possible to suppress mixing of the first chemical liquid with the second chemical liquid.

As described above, the delivery position R where the delivery table 150 that supports the substrate W is disposed is provided inside the chamber 11. Therefore, the substrate holding portion 200 does not have to directly pass or receive the substrate W to or from the center robot CR. Therefore, even during the operation of the substrate holding portion 200, the center robot CR can deliver and receive the substrate W to and from the delivery table 150. Further, even during the operation of the center robot CR, the substrate holding portion 200 can deliver and receive the substrate W to and from the delivery table 150. Therefore, when the substrate W is delivered between the center robot CR and the substrate holding portion 200, it is possible to suppress the occurrence of a standby time in the center robot CR or the substrate holding portion 200.

As described above, the moving mechanism 300 moves the substrate holding portion 200 about the turning axis L200, the processing position Q and the cleaning position CW are located on the circle C200 centered on the turning axis L200, and the moving mechanism 300 moves the substrate holding portion 200 between the processing position Q and the cleaning position CW in the chamber 11. Therefore, the substrate holding portion 200 can be easily moved between the processing position Q and the cleaning position CW.

As described above, out of the processing position Q and the cleaning position CW, the cleaning position CW is located farthest from the opening 12. Therefore, it is possible to suppress the processing position Q from being located farthest from the opening 12. As a result, it is possible to suppress an increase in the distance from the position where the substrate W is processed to the opening 12, so that it is possible to suppress an increase in the transfer distance of the substrate W. Therefore, it is possible to suppress an increase in time required for the processing.

Further, the processing using the chemical liquid and the processing using the rinse liquid are performed at different processing positions. Therefore, it is not necessary to replace the processing liquid stored in the immersion bath 400 every time the processing is performed.

Next, a substrate processing unit 10 in the substrate processing apparatus 100 according to the first preferred embodiment will be described with reference to FIGS. 5 and 6. FIG. 5 is a schematic diagram of the substrate processing unit 10 in the substrate processing apparatus 100 according to the first preferred embodiment. FIG. 6 is a schematic diagram illustrating a structure around the substrate holding portion 200 and the moving mechanism 300 of the substrate processing apparatus 100 according to the first preferred embodiment. In FIG. 5 and the subsequent drawings, all of various supplying portions and all of discharge portions may be drawn inside the chamber 11 due to the limitation of the drawing size, but some of various supplying portions and some of the discharge portions are disposed outside the chamber 11.

As illustrated in FIG. 5, the substrate processing unit 10 according to the first preferred embodiment includes a plurality of processing positions Q as described above. In the present preferred embodiment, the plurality of processing positions Q are similarly configured. Therefore, one processing position Q will be described, and description of the remaining processing positions Q will be omitted.

Specifically, the substrate processing unit 10 includes an air blowing unit 14, a cup 450, and an immersion bath supporting portion 500 in addition to the chamber 11, the substrate holding portion 200, the moving mechanism 300, and the immersion bath 400 described above. For example, one chamber 11, one substrate holding portion 200, one moving mechanism 300, one air blowing unit 14, and one immersion bath supporting portion 500 are provided for one substrate processing unit 10. On the other hand, one immersion bath 400 and one cup 450 are provided for one processing position Q. The air blowing unit 14 is controlled by the controlling portion 102.

The air blowing unit 14 is disposed on the upper portion of or above the chamber 11. For example, the air blowing unit 14 is disposed on the top surface of the chamber 11. The air blowing unit 14 sends air into the chamber 11. The air blowing unit 14 includes, for example, a fan filter unit (FFU). A downflow (downward flow) is formed in the chamber 11 by the air blowing unit 14 and an exhaust device (not illustrated).

The immersion bath 400 stores a processing liquid. Specifically, the immersion bath 400 has a container shape with an open upper surface, and the processing liquid is stored in the inner space 400a (see FIG. 6) of the immersion bath 400. In addition, the immersion bath 400 accommodates the substrate W. The substrate W is immersed in the processing liquid stored in the immersion bath 400. As a result, the substrate W is processed with the processing liquid.

The immersion bath 400 has, for example, a substantially circular shape in a plan view. The immersion bath 400 may have a bottomed cylindrical shape. The immersion bath 400 is supported in a horizontal posture by the immersion bath supporting portion 500. Note that the immersion bath 400 may be installed in a horizontal posture on the bottom surface (bottom wall) of the chamber 11. For example, the immersion bath 400 may be made of silicon carbide (SiC) or stainless steel. For example, the immersion bath 400 may be made of aluminum coated with a fluororesin. The fluororesin includes, for example, polytetrafluoroethylene (PTFE).

As illustrated in FIG. 6, the immersion bath 400 has a bottom wall 401 and a side wall 402. The bottom wall 401 may have a circular shape in a plan view. The side wall 402 is connected to the bottom wall 401. The side wall 402 may be connected to an end portion (peripheral edge portion) of the bottom wall 401. The side wall 402 extends upward from the bottom wall 401. An inner space 400a of the immersion bath 400 is formed by the bottom wall 401 and the side wall 402. In other words, the inner space 400a is a space surrounded by the bottom wall 401 and the side wall 402.

More specifically, the side wall 402 has an inner peripheral surface 402a, an outer peripheral surface 402b, and an upper surface 402c. The inner peripheral surface 402a defines the inner space 400a. The outer peripheral surface 402b is disposed outside the inner peripheral surface 402a. The upper surface 402c connects the upper end of the inner peripheral surface 402a and the upper end of the outer peripheral surface 402b. The upper surface 402c is inclined downward toward the outside.

In the first preferred embodiment, a support table 410 is provided on the bottom wall 401 of the immersion bath 400. The support table 410 supports the substrate W. The support table 410 protrudes upward from the upper surface of the bottom wall 401. The support table 410 has, for example, a cylindrical shape, which does not limit the support table 410. A plurality of support tables 410 are provided on the bottom wall 401. Note that the support table 410 and the bottom wall 401 may be integrally formed. In other words, the support table 410 and the bottom wall 401 may be a single member.

The cup 450 is disposed around the periphery of the immersion bath 400. In the present preferred embodiment, the cup 450 and the immersion bath 400 are integrally formed. In other words, the cup 450 and the immersion bath 400 are a single member.

The cup 450 is disposed outside the side wall 402 of the immersion bath 400 at a predetermined distance from the side wall 402. Specifically, the cup 450 has a bottom wall 451 and a side wall 452. The bottom wall 451 is connected to the bottom wall 401 or the side wall 402 of the immersion bath 400. The side wall 452 is connected to a peripheral edge portion of the bottom wall 451. The side wall 452 has a lower wall portion 452a and an upper wall portion 452b. The lower wall portion 452a extends upward from the bottom wall 451. The upper wall portion 452b is inclined inward and upward from the upper end of the lower wall portion 452a. The bottom wall 451 and the side wall 452 of the cup 450 and the side wall 402 of the immersion bath 400 define an inner space 450a of the cup 450.

For example, the cup 450 collects the processing liquid that is scattered around the periphery of the substrate W due to the rotation of the substrate W. An exhaust device (not illustrated) may be connected to the cup 450, and a gas in the inner space 450a may be exhausted out of the chamber 11.

The immersion bath supporting portion 500 supports the immersion bath 400. In the present preferred embodiment, the immersion bath supporting portion 500 supports the immersion bath 400 and the cup 450. The immersion bath supporting portion 500 includes a support plate 502. The support plate 502 has a plate shape and is disposed in a horizontal posture. For example, the support plate 502 may be fixed to a side wall of the chamber 11, or may be fixed to an upper surface of a support column, etc., of the immersion bath supporting portion 500. In the present preferred embodiment, the support plate 502 is fixed to the side wall of the chamber 11, and partitions the inside of the chamber 11 into an upper space and a lower space. The support plate 502 supports the immersion bath 400 in a horizontal posture. A through hole 502a penetrating the support plate 502 in the thickness direction is formed at a predetermined position of the support plate 502. A screw shaft 311 that will be described later of the moving mechanism 300 is inserted into the through hole 502a.

As illustrated in FIG. 5, the substrate processing apparatus 100 includes a first supplying portion 30, a second supplying portion 40, a first discharge portion 50, and a second discharge portion 60. The first supplying portion 30, the second supplying portion 40, the first discharge portion 50, and the second discharge portion 60 are controlled by the controlling portion 102.

The first supplying portion 30 supplies the processing liquid to the immersion bath 400. The first supplying portion 30 supplies the processing liquid from above the immersion bath 400. In the present preferred embodiment, the first supplying portion 30 can eject the processing liquid toward the upper surface Wa of the substrate W held by the substrate holding portion 200.

Specifically, the first supplying portion 30 includes a first chemical liquid piping 31, a second chemical liquid piping 32, a rinse liquid piping 33, a common piping 34, an opening/closing valve 35, an opening/closing valve 36, an opening/closing valve 37, and a nozzle 38.

The first chemical liquid piping 31, the second chemical liquid piping 32, the rinse liquid piping 33, and the common piping 34 are tubular members, and allow the processing liquid to flow therethrough.

The first chemical liquid is supplied from a supply source to the first chemical liquid piping 31. A downstream end of the first chemical liquid piping 31 is connected to the common piping 34. The opening/closing valve 35 is provided in the first chemical liquid piping 31 and opens and closes a flow path in the first chemical liquid piping 31. The opening/closing valve 35 adjusts the opening degree of the first chemical liquid piping 31 to adjust a flow rate of the first chemical liquid supplied to the first chemical liquid piping 31.

A second chemical liquid is supplied from a supply source to the second chemical liquid piping 32. The downstream end of the second chemical liquid piping 32 is connected to the common piping 34. The opening/closing valve 36 is provided in the second chemical liquid piping 32 and opens and closes a flow path in the second chemical liquid piping 32. The opening/closing valve 36 adjusts the opening degree of the second chemical liquid piping 32 to adjust a flow rate of the second chemical liquid supplied to the second chemical liquid piping 32.

A rinse liquid is supplied from a supply source to the rinse liquid piping 33. The downstream end of the rinse liquid piping 33 is connected to the common piping 34. The opening/closing valve 37 is provided in the rinse liquid piping 33, and opens and closes a flow path in the rinse liquid piping 33. The opening/closing valve 37 adjusts the opening degree of the rinse liquid piping 33 to adjust a flow rate of the rinse liquid supplied to the rinse liquid piping 33.

Each of the opening/closing valve 35 to the opening/closing valve 37 includes a valve body (not illustrated) inside which a valve seat is provided, a valve element that opens and closes the valve seat, and an actuator (not illustrated) that moves the valve element between an open position and a closed position.

The downstream end of the common piping 34 is connected to the nozzle 38. The common piping 34 allows the processing liquid to flow through the nozzle 38.

The nozzle 38 ejects the processing liquid. In the present preferred embodiment, the nozzle 38 ejects the processing liquid toward the upper surface Wa of the substrate W held by the substrate holding portion 200. Note that the nozzle 38 may also eject the processing liquid to the immersion bath 400 in a state in which the substrate holding portion 200 does not hold the substrate W. The nozzle 38 is provided in a spin base 201 that will be described later of the substrate holding portion 200. The nozzle 38 is disposed, for example, at the central portion of the spin base 201. In the present preferred embodiment, the nozzle 38 is disposed on a rotational axis AX1 of the spin base 201. The nozzle 38 may be formed separately from the spin base 201, or may be formed by a portion of the spin base 201. In a case where the nozzle 38 is formed separately from the spin base 201, for example, a through hole extending in the up-down direction may be formed at the central portion of the spin base 201, and the nozzle 38 may be disposed in the through hole of the spin base 201. In this case, the nozzle 38 may be fixed to a housing 205.

The second supplying portion 40 supplies the processing liquid to the immersion bath 400. The second supplying portion 40 supplies the processing liquid from below the immersion bath 400. In the present preferred embodiment, the second supplying portion 40 can eject the processing liquid toward the lower surface Wb of the substrate W held by the substrate holding portion 200.

Specifically, the second supplying portion 40 includes a first chemical liquid piping 41, a second chemical liquid piping 42, a rinse liquid piping 43, a common piping 44, an opening/closing valve 45, an opening/closing valve 46, an opening/closing valve 47, and a nozzle 48.

The first chemical liquid piping 41, the second chemical liquid piping 42, the rinse liquid piping 43, and the common piping 44 are annular members, and allow the processing liquid to flow therethrough.

The first chemical liquid is supplied from a supply source to the first chemical liquid piping 41. The downstream end of the first chemical liquid piping 41 is connected to the common piping 44. The opening/closing valve 45 is provided in the first chemical liquid piping 41 and opens and closes a flow path in the first chemical liquid piping 41. The opening/closing valve 45 adjusts the opening degree of the first chemical liquid piping 41 to adjust a flow rate of the first chemical liquid supplied to the first chemical liquid piping 41.

The second chemical liquid is supplied from a supply source to the second chemical liquid piping 42. The downstream end of the second chemical liquid piping 42 is connected to the common piping 44. The opening/closing valve 46 is provided in the second chemical liquid piping 42 and opens and closes a flow path in the second chemical liquid piping 42. The opening/closing valve 46 adjusts the opening degree of the second chemical liquid piping 42 to adjust a flow rate of the second chemical liquid supplied to the second chemical liquid piping 42.

The rinse liquid is supplied from a supply source to the rinse liquid piping 43. The downstream end of the rinse liquid piping 43 is connected to the common piping 44. The opening/closing valve 47 is provided in the rinse liquid piping 43, and opens and closes a flow path in the rinse liquid piping 43. The opening/closing valve 47 adjusts the opening degree of the rinse liquid piping 43 to adjust a flow rate of the rinse liquid supplied to the rinse liquid piping 43.

Each of the opening/closing valve 45 to the opening/closing valve 47 includes a valve body (not illustrated) inside which a valve seat is provided, a valve element that opens and closes the valve seat, and an actuator (not illustrated) that moves the valve element between an open position and a closed position.

The downstream end of the common piping 44 is connected to the nozzle 48. The common piping 44 allows the processing liquid to flow through the nozzle 48.

The nozzle 48 ejects the processing liquid. In the present preferred embodiment, the nozzle 48 ejects the processing liquid toward the lower surface Wb of the substrate W held by the substrate holding portion 200. Note that the nozzle 48 may also eject the processing liquid to the immersion bath 400 in a state in which the substrate holding portion 200 does not hold the substrate W. The nozzle 48 is disposed at the central portion of the immersion bath 400. The tip (upper end) of the nozzle 48 protrudes upward from the upper surface of the bottom wall 401 of the immersion bath 400. The nozzle 48 may be formed separately from the immersion bath 400, or may be formed by a portion of the immersion bath 400.

The first discharge portion 50 discharges the processing liquid stored in the immersion bath 400 out of the immersion bath 400. In the present preferred embodiment, the first discharge portion 50 discharges the processing liquid stored in the immersion bath 400 out of the chamber 11.

Specifically, the first discharge portion 50 includes a common piping 51, a drain piping 52, a return piping 53, an opening/closing valve 54, and an opening/closing valve 55. The common piping 51, the drain piping 52, and the return piping 53 are tubular members, and allow the processing liquid to flow therethrough.

The upstream end of the common piping 51 is connected to the bottom wall 401 of the immersion bath 400. The common piping 51 communicates with the inner space 400a of the immersion bath 400. The processing liquid in the immersion bath 400 flows into the common piping 51. The downstream end of the common piping 51 is connected to the drain piping 52 and the return piping 53.

The drain piping 52 drains the processing liquid from the common piping 51. For example, the drain piping 52 allows the processing liquid from the common piping 51 to flow through a drain tank (not illustrated). The opening/closing valve 54 is provided in the drain piping 52 and opens and closes a flow path in the drain piping 52.

The return piping 53 returns the processing liquid from the common piping 51 to a processing liquid cabinet (not illustrated) provided in the substrate processing apparatus 100. The processing liquid returned to the processing liquid cabinet is reused. Therefore, since the amount of the processing liquid used can be decreased, the environmental load can be reduced. The opening/closing valve 55 is provided in the return piping 53 to open and close a flow path in the return piping 53.

Each of the opening/closing valve 54 and the opening/closing valve 55 includes a valve body (not illustrated) inside which a valve seat is provided, a valve element that opens and closes the valve seat, and an actuator (not illustrated) that moves the valve element between an open position and a closed position.

The second discharge portion 60 discharges the processing liquid in the cup 450 out of the cup 450. In the present preferred embodiment, the second discharge portion 60 discharges the processing liquid in the cup 450 out of the chamber 11.

Specifically, the second discharge portion 60 includes a drain piping 61 and an opening/closing valve 62. The drain piping 61 is a tubular member and allows the processing liquid to flow therethrough.

The drain piping 61 drains the processing liquid in the cup 450. Specifically, the upstream end of the drain piping 61 is connected to the bottom wall 451 of the cup 450. The drain piping 61 communicates with the inner space 450a of the cup 450. The processing liquid of the cup 450 flows into the drain piping 61. For example, the drain piping 61 allows the processing liquid to flow through a drain tank (not illustrated). The opening/closing valve 62 is provided in the drain piping 61 and opens and closes a flow path in the drain piping 61. The opening/closing valve 62 includes a valve body (not illustrated) inside which a valve seat is provided, a valve element that opens and closes the valve seat, and an actuator (not illustrated) that moves the valve element between an open position and a closed position.

Next, the substrate holding portion 200 and the moving mechanism 300 will be further described with reference to FIG. 6.

As illustrated in FIG. 6, the substrate holding portion 200 includes a spin base 201, a chuck pin 202, a shaft 203, an electric motor 204, and a housing 205. Note that the spin base 201 is an example of a “base” of the present invention. The chuck pin 202 is an example of a “contact member” of the present invention. The electric motor 204 is an example of a “rotation driving portion” of the present invention.

The chuck pin 202 is provided on the spin base 201 disposed above the substrate W. The chuck pin 202 comes into contact with the substrate W to chuck the substrate W. Typically, the spin base 201 is provided with a plurality of chuck pins 202. The chuck pin 202 protrudes downward from a lower surface of the spin base 201. The chuck pin 202 has a pin-shaped portion extending in the up-down direction and a contact portion provided at the lower end of the pin-shaped portion and in contact with the circumferential edge of the substrate W. Each chuck pin 202 is rotatable about a rotational axis AX2 (a central axis of each pin-shaped portion) extending in the up-down direction. The chuck pin 202 rotates about the rotational axis AX2 between a holding position where the substrate W is held and a non-holding position where the substrate W is not held.

The shaft 203 is a hollow shaft. The shaft 203 extends in the vertical direction along the rotational axis AX1. The spin base 201 is coupled to the lower end of the shaft 203. The substrate W is located below the spin base 201.

The spin base 201 has a disk shape and horizontally supports the substrate W. The shaft 203 extends upward from a central portion of the spin base 201. The electric motor 204 applies a rotational force to the shaft 203. The electric motor 204 rotates the shaft 203 in the rotation direction to rotate the substrate W and the spin base 201 around the rotational axis AX1. The housing 205 has a substantially box shape and accommodates a portion of the shaft 203 and the electric motor 204. The electric motor 204 is attached to a predetermined position of the housing 205.

In addition, the substrate holding portion 200 includes a chuck driving mechanism 210 that rotates the plurality of chuck pins 202. The chuck driving mechanism 210 is configured by using a known technique (for example, Japanese Patent Application Publication No. 2016-25186), and will thus be briefly described.

The chuck driving mechanism 210 includes a driving magnet 211, a driven magnet 212, and a lifting/lowering plate 213. The driving magnet 211 is disposed in the housing 205. The driving magnet 211 is disposed over one turn to surround the rotational axis AX1. The driving magnet 211 is moved in the up-down direction with respect to the housing 205 by a lifting/lowering mechanism (not illustrated). The driven magnet 212 and the lifting/lowering plate 213 are disposed in the spin base 201. The driven magnet 212 is fixed to the lifting/lowering plate 213. The lifting/lowering plate 213 is biased upward by a biasing member (not illustrated). The driven magnet 212 and the lifting/lowering plate 213 are disposed over one turn to surround the rotational axis AX1. The driven magnet 212 is disposed at a position directly below the driving magnet 211. The driven magnet 212 is disposed to repel the driving magnet 211. Specifically, the driven magnet 212 and the driving magnet 211 are disposed such that the surfaces facing each other have the same polarity. The lifting/lowering plate 213 is provided with a cam or a link mechanism that rotates the chuck pin 202 between the holding position and the non-holding position. When the driving magnet 211 is lifted and lowered, the driven magnet 212 and the lifting/lowering plate 213 are lifted and lowered. As a result, the chuck pin 202 is rotated between the holding position and the non-holding position, whereby the substrate W is held by the chuck pin 202 or released from the holding.

The moving mechanism 300 includes a lifting/lowering mechanism 310 that moves the substrate holding portion 200 in the vertical direction, and a turning mechanism 320 that turns the substrate holding portion 200. The lifting/lowering mechanism 310 includes, for example, the screw shaft 311, a nut 312, an electric motor 313, and a driving belt 314.

The screw shaft 311 and the nut 312 configure a ball screw mechanism. The screw shaft 311 extends in the vertical direction. An upper end of the screw shaft 311 is fixed to the housing 205 of the substrate holding portion 200. A screw groove is formed on the outer peripheral surface of the screw shaft 311.

The nut 312 has a ball that contacts the screw groove of the screw shaft 311. Since the nut 312 rotates about a central axis AX3 of the screw shaft 311, the screw shaft 311 moves in the vertical direction. In the present preferred embodiment, the central axis AX3 coincides with the turning axis L200.

The electric motor 313 includes, for example, a motor body 313a capable of rotating forward and backward, a motor shaft 313b, and a motor pulley 313c. The motor body 313a is fixed to a motor supporting member 321 that will be described later of the turning mechanism 320. The motor pulley 313c is fixed to the tip of the motor shaft 313b.

The driving belt 314 is stretched around outer peripheral surfaces of the motor pulley 313c and the nut 312. The driving belt 314 transmits the rotational force of the motor pulley 313c to the nut 312. As a result, when the motor pulley 313c is rotated, the nut 312 is rotated. Note that the screw shaft 311 is arranged not to move in the horizontal direction.

In the moving mechanism 300, when the electric motor 313 of the lifting/lowering 310 is driven, the driving force of the electric motor 313 is transmitted to the nut 312 through the driving belt 314. The nut 312 is then rotated, whereby the screw shaft 311 is lifted and lowered in the vertical direction.

The turning mechanism 320 includes, for example, the motor supporting member 321, an electric motor 322, and a driving belt 323.

The motor supporting member 321 supports the electric motor 313 of the lifting/lowering mechanism 310. The motor supporting member 321 includes a support plate 321a and a pulley 321b fixed to the support plate 321a. The screw shaft 311 is inserted through the central portion of the pulley 321b. The motor supporting member 321 is rotated (turned) about the central axis AX3 of the screw shaft 311 together with the electric motor 313.

The electric motor 322 includes, for example, a motor body 322a, a motor shaft 322b, and a motor pulley 322c. The motor body 322a is fixed to the support plate 502. The motor pulley 322c is fixed to the tip of the motor shaft 322b.

The driving belt 323 is stretched between the motor pulley 322c and the pulley 321b of the motor supporting member 321. The driving belt 323 transmits the rotational force of the motor pulley 322c to the motor supporting member 321. As a result, when the motor pulley 322c is rotated, the motor supporting member 321 is turned about the central axis AX3 (turning axis L200).

In the moving mechanism 300, when the electric motor 322 is driven, the driving force of the electric motor 322 is transmitted to the motor supporting member 321 through the driving belt 323. As the motor supporting member 321 turns, the lifting/lowering mechanism 310 and the substrate holding portion 200 turn about the central axis AX3 (turning axis L200).

The moving mechanism 300 includes a shaft cover 330. The shaft cover 330 includes a bellows portion 330a that can expand and contract in the vertical direction, an upper plate 330b that attaches an upper end of the bellows portion 330a to the housing 205 of the substrate holding portion 200, and a lower plate 330c that attaches a lower end of the bellows portion 330a to the support plate 502.

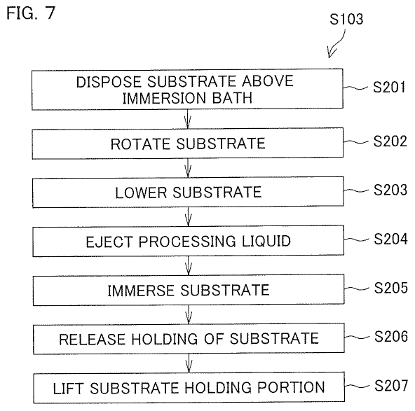

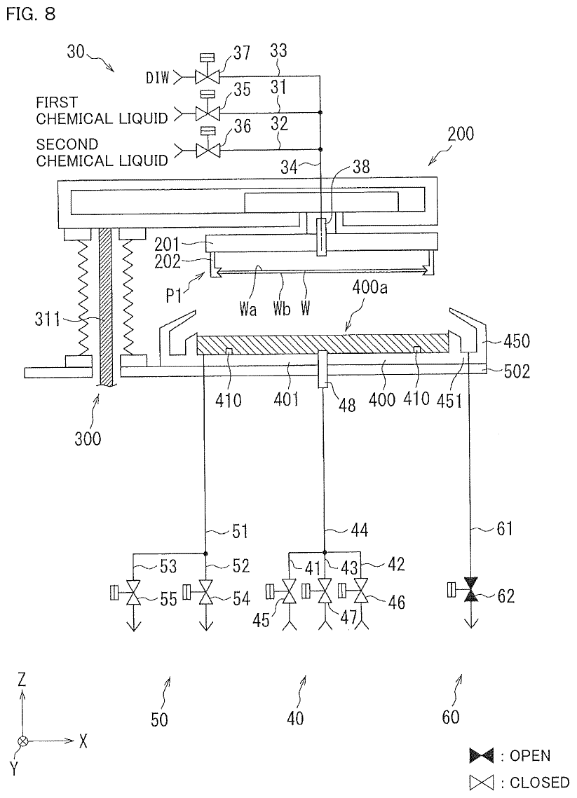

Next, a method of immersing the substrate W in a processing liquid (steps S103, S105, S107, and S109) will be described in detail with reference to FIGS. 7 to 10. Here, a method of immersing the substrate W in step S103 will be described, but the same applies to the method of immersing the substrate W in steps S105, S107, and S109. FIG. 7 is a flowchart illustrating a method of immersing the substrate W in a processing liquid. FIGS. 8 to 10 are schematic diagrams for describing a method of immersing the substrate W in a processing liquid.

As illustrated in FIG. 7, in step S201, the substrate W is disposed above the immersion bath 400 (see FIG. 8). Specifically, the controlling portion 102 controls the moving mechanism 300 to locate the substrate holding portion 200 above the immersion bath 400. Note that the opening/closing valves 35 to 37, 45 to 47, 54, and 55 are in a closed state, and the opening/closing valve 62 is in an open state.

Next, in step S202, the substrate W is rotated. Specifically, the controlling portion 102 controls the substrate holding portion 200 to rotate the spin base 201. As a result, the rotation of the substrate W is started.

Next, in step S203, the substrate W is lowered. Specifically, the controlling portion 102 controls the moving mechanism 300 to start lowering the substrate holding portion 200. As a result, the substrate W is lowered while being rotated.

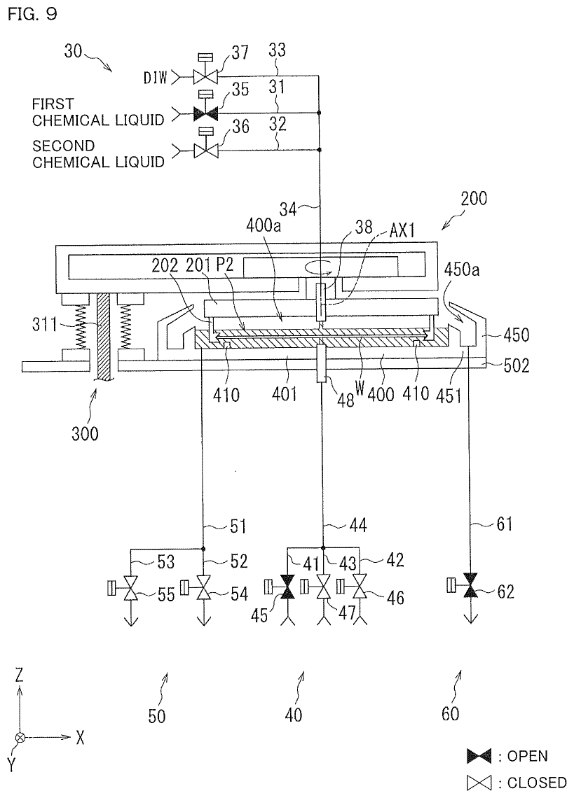

Next, in step S204, as illustrated in FIG. 9, the processing liquid (here, the first chemical liquid) is ejected. Specifically, the controlling portion 102 switches at least one of the opening/closing valve 35 and the opening/closing valve 45 from the closed state to the open state. As a result, the first chemical liquid is ejected from at least one of the nozzle 38 and the nozzle 48 toward the substrate W. In the present preferred embodiment, the controlling portion 102 switches the opening/closing valve 35 and the opening/closing valve 45 from the closed state to the open state. Thereby, the first chemical liquid is ejected from the nozzle 38 and the nozzle 48 toward the substrate W.

As described above, in the present preferred embodiment, while at least one of the first supplying portion 30 and the second supplying portion 40 is supplying the first chemical liquid toward the substrate W, the moving mechanism 300 immerses the substrate W in the first chemical liquid stored in advance in the immersion bath 400. In the present preferred embodiment, while both the first supplying portion 30 and the second supplying portion 40 are supplying the first chemical liquid toward the substrate W, the moving mechanism 300 immerses the substrate W in the first chemical liquid stored in advance in the immersion bath 400. In step S204, it is preferable that at least the second supplying portion 40 supplies the first chemical liquid toward the substrate W.

Next, in step S205, the substrate W is immersed in a processing liquid (here, the first chemical liquid). That is, the upper surface Wa of the substrate W is located below the liquid level of the processing liquid (here, the first chemical liquid). The controlling portion 102 controls the substrate holding portion 200 to stop the rotation of the spin base 201, stop the lowering of the substrate holding portion 200, and switch the opening/closing valve 35 and the opening/closing valve 45 from the open state to the closed state. As a result, the rotation of the substrate W is stopped, and the ejection of the processing liquid is stopped.

Next, in step S206, the holding of the substrate W is released. Specifically, the controlling portion 102 controls the substrate holding portion 200 to release the holding of the substrate W. As a result, the substrate W is placed on the support table 410.

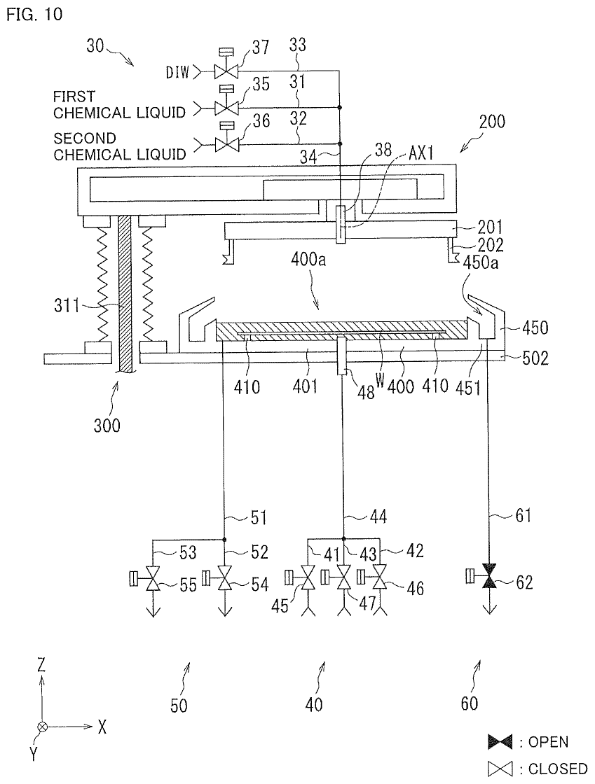

Next, in step S207, as illustrated in FIG. 10, the substrate holding portion 200 is lifted. Specifically, the controlling portion 102 controls the moving mechanism 300 to lift the substrate holding portion 200.

In the present preferred embodiment, as described above, the immersion bath 400 is provided with the support table 410 that supports the substrate W. Therefore, by placing the substrate W on the support table 410, the substrate holding portion 200 does not have to keep holding the substrate W at the time of processing. Therefore, the substrate holding portion 200 can be cleaned in parallel with the processing on the substrate W. In addition, by providing the support table 410, as described later, the substrate holding portion 200 can also be moved to, for example, another processing position Q to hold or transfer another substrate W.

As described above, the substrate holding portion 200 includes the spin base 201 disposed above the substrate W and the plurality of chuck pins 202 protruding downward from the spin base 201 and holding the circumferential edge of the substrate W. Therefore, since the substrate W can be held from above, the substrate W can be easily immersed in the processing liquid in the immersion bath 400.

The first supplying portion 30 includes the nozzle 38 that ejects the processing liquid toward the upper surface Wa of the substrate W, and the nozzle 38 is provided in the spin base 201. Therefore, in the configuration in which the spin base 201 is provided above the substrate W, the processing liquid can be easily ejected to the upper surface Wa of the substrate W.

In addition, while the substrate holding portion 200 is rotating the substrate W, the moving mechanism 300 immerses the substrate W in the processing liquid stored in advance in the immersion bath 400. Therefore, the air existing between a lower surface Wb of the substrate W and a liquid level of the processing liquid is easily discharged to the radially outer side of the substrate W. Therefore, the substrate W can be easily immersed in the processing liquid.

Further, while the second supplying portion 40 is supplying the processing liquid toward the substrate W, the moving mechanism 300 immerses the substrate W in the processing liquid stored in advance in the immersion bath 400. Therefore, the air existing between the lower surface Wb of the substrate W and the liquid level of the processing liquid is easily discharged radially outward of the substrate w by the processing liquid supplied from the second supplying portion 40. Therefore, the substrate W can be more easily immersed in the processing liquid.

In addition, while the first supplying portion 30 is supplying the processing liquid toward the substrate W, the moving mechanism 300 immerses the substrate W in the processing liquid stored in advance in the immersion bath 400. Therefore, since the upper surface Wa of the substrate W is wetted by the processing liquid supplied from the first supplying portion 30, the processing liquid stored in the immersion bath 400 easily flows into the upper surface Wa of the substrate W. In addition, since the timing at which the processing liquid comes into contact with the upper surface Wa of the substrate W (the timing at which the processing starts) is advanced, the cycle time can be shortened.

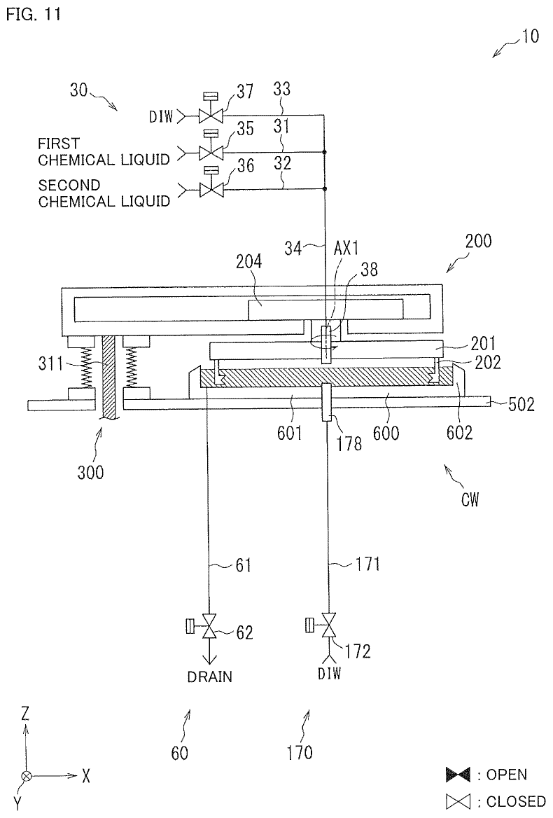

Next, the substrate processing unit 10 in the substrate processing apparatus 100 according to the first preferred embodiment will be further described with reference to FIG. 11. FIG. 11 is a schematic diagram illustrating a structure around the cleaning bath 600 of the substrate processing apparatus 100.

As illustrated in FIG. 11, the cleaning bath 600 is a bath to clean the chuck pins 202 of the substrate holding portion 200. In the cleaning bath 600, a rinse liquid (here, DIW) which is a cleaning liquid is stored.

The cleaning bath 600 stores a cleaning liquid. The cleaning bath 600 has a container shape with an open upper surface, and accommodates a tip portion (contact portion) of the chuck pin 202. The chuck pins 202 of the substrate holding portion 200 are immersed in the cleaning liquid stored in the cleaning bath 600 in a state of not holding the substrate W. As a result, the chuck pins 202 are cleaned by the cleaning liquid. In the present preferred embodiment, the substrate holding portion 200 rotates the spin base 201 about the rotational axis AX1 in a state in which the chuck pins 202 are immersed in the cleaning liquid. That is, in steps S104, S106, S108, and S110, the substrate holding portion 200 rotates the spin base 201 in a state in which the chuck pins 202 are immersed in the cleaning liquid. Therefore, the cleaning effect on the chuck pins 202 can be improved.

The cleaning bath 600 has the same structure as that of the immersion bath 400. Specifically, the cleaning bath 600 has a bottom wall 601 and a side wall 602. Note that configurations of the bottom wall 601 and the side wall 602 are similar to the configurations of the bottom wall 401 and the side wall 402 of the immersion bath 400.

The substrate processing apparatus 100 includes a third supplying portion 170. The third supplying portion 170 is controlled by the controlling portion 102.

The third supplying portion 170 supplies the rinse liquid to the cleaning bath 600. The third supplying portion 170 supplies the rinse liquid from below the cleaning bath 600.

The third supplying portion 170 includes a rinse liquid piping 171, an opening/closing valve 172, and a nozzle 178. The nozzle 178 is connected to the bottom wall 601 of the cleaning bath 600, and ejects the rinse liquid to the inside of the cleaning bath 600. Other configurations of the rinse liquid piping 171, the opening/closing valve 172, and the nozzle 178 are similar to, for example, the configurations of the rinse liquid piping 43, the opening/closing valve 47, and the nozzle 48.

The substrate processing apparatus 100 also includes the second discharge portion 60. The second discharge portion 60 is connected to a lower portion of the cleaning bath 600. The second discharge portion 60 discharges the rinse liquid in the cleaning bath 600 out of the cleaning bath 600.

In the present preferred embodiment, as described above, the electric motor 204 of the substrate holding portion 200 rotates the chuck pins 202 in a state in which the chuck pins 202 are immersed in the cleaning liquid. Therefore, the cleaning effect on the chuck pins 202 can be improved.

In the first preferred embodiment, an example in which the chuck pins 202 are cleaned every time the substrate W is immersed in a chemical liquid (the first chemical liquid and the second chemical liquid) and a rinse liquid has been described, but the present invention is not limited thereto. For example, the chuck pins 202 may be cleaned only after the substrate W is immersed in a chemical liquid. In addition, for example, the chuck pins 202 may be cleaned only after the substrate W is immersed in a rinse liquid. In addition, for example, the chuck pins 202 may be cleaned every time the processing on one substrate W is completed.

### Second Preferred Embodiment

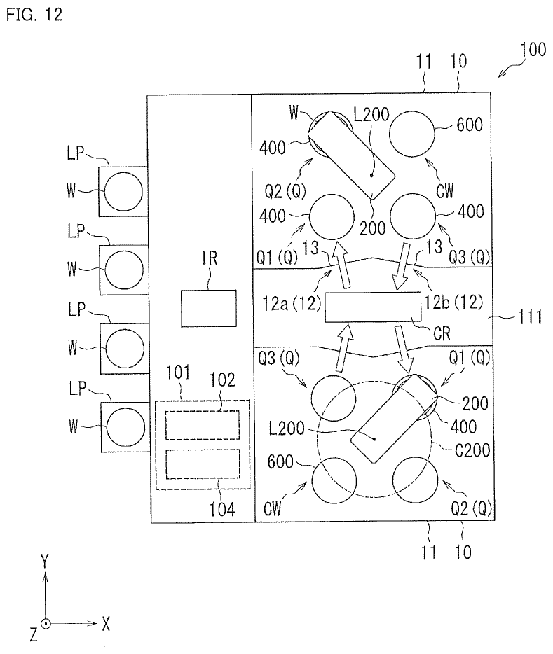

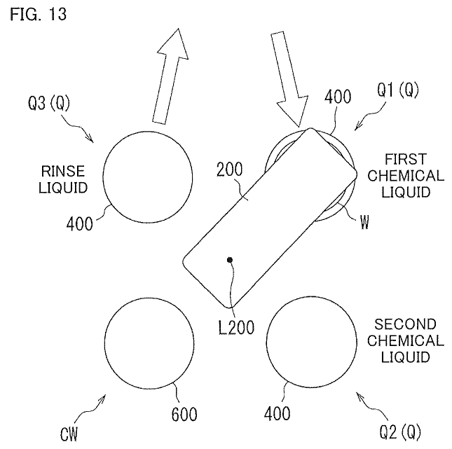

Next, a substrate processing apparatus 100 according to a second preferred embodiment of the present invention will be described with reference to FIGS. 12 to 14. FIG. 12 is a schematic plan view of the substrate processing apparatus 100 according to the second preferred embodiment. FIG. 13 is a schematic plan view illustrating the inside of one chamber 11 of the substrate processing apparatus 100 according to the second preferred embodiment. In the second preferred embodiment, unlike the first preferred embodiment, an example in which the substrate holding portion 200 can perform one rotation about the turning axis L200 will be described.

As illustrated in FIG. 12, in the present preferred embodiment, the chamber 11 has at least two (here, two) openings 12. At least two (here, two) shutters 13 are provided, that is, provided in the same number as the number of the openings 12. Each opening 12 is located between the center robot CR and the processing position Q in a state in which the center robot CR is disposed at a predetermined position (for example, the position illustrated in FIG. 12).

In the present preferred embodiment, the substrate W is carried in or out through each opening 12. Specifically, one opening 12 of the two openings 12 is set as a first opening 12a, and the other opening 12 of the two openings 12 is set as a second opening 12b. The first opening 12a is a carry-in port through which the substrate W is carried from the outside to the inside of the chamber 11. The second opening 12b is a carry-out port through which the substrate W is carried from the inside of the chamber 11 to the outside.

As illustrated in FIGS. 12 and 13, in the present preferred embodiment, as in the first preferred embodiment, a plurality of (here, three) processing positions Q (a processing position Q1, a processing position Q2, and a processing position Q3) and a cleaning position CW are provided in each chamber 11. In the present preferred embodiment, the delivery position R is not provided.

The processing position Q1, the processing position Q2, the cleaning position CW, and the processing position Q3 are disposed in order in the clockwise direction. In addition, the processing position Q1 is disposed at a position closer to the first opening 12a than the other two processing positions Q and the cleaning position CW. That is, the processing position Q1 is disposed to face the first opening 12a. The processing position Q1 is a position where the substrate W is carried in. In addition, the processing position Q3 is disposed at a position closer to the second opening 12b than the other two processing positions Q and the cleaning position CW. That is, the processing position Q3 is disposed to face the second opening 12b. The processing position Q3 is a position where the substrate W is carried out.

In the present preferred embodiment, the substrate holding portion 200 can perform one rotation (one turn) or more around the turning axis L200.

Further, in the present preferred embodiment, the plurality of processing positions Q are disposed over a half turn or more (here, about) 180° around the turning axis L200. For example, the plurality of processing positions Q are disposed at intervals of 90°. In the present preferred embodiment, the plurality of processing positions Q and the cleaning position CW are disposed around the turning axis L200 over about one turn.

In the present preferred embodiment, as in the first preferred embodiment, the cleaning position CW and the cleaning bath 600 are disposed farthest from the position (here, the processing position Q1 and the processing position Q3) where the substrate W is delivered to and from the center robot CR. In the present preferred embodiment, the distance from the processing position Q3 to the cleaning position CW and the distance from the processing position Q2 to the processing position Q1 are the same.

Other structures of the second preferred embodiment are similar to those of the first preferred embodiment.

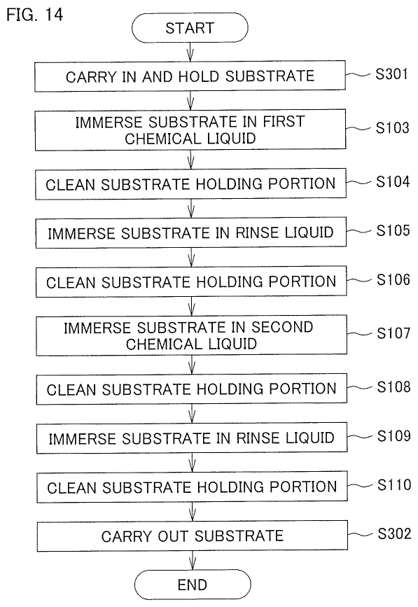

Next, a substrate processing method according to the second preferred embodiment will be described with reference to FIG. 14. FIG. 14 is a flowchart illustrating a substrate processing method according to the second preferred embodiment. The substrate processing method performed by the substrate processing apparatus 100 according to the second preferred embodiment includes steps S301, S103 to S110, and S302.

As illustrated in FIG. 14, in step S301, the substrate W is carried into the chamber 11 and held by the substrate holding portion 200. Specifically, the controlling portion 102 controls the center robot CR to carry the substrate W supported by the arm of the center robot CR into the chamber 11. In this case, the substrate holding portion 200 is located at the processing position Q1, and the substrate W is carried into the chamber 11 through the first opening 12a.

The controlling portion 102 controls the center robot CR and the substrate holding portion 200 to deliver the substrate W from the center robot CR to the substrate holding portion 200. As a result, the substrate holding portion 200 holds the substrate W.

Next, steps S103 to S110 are executed in the same manner as in the first preferred embodiment.

Next, in step S302, the substrate W is held by the substrate holding portion 200 and carried out of the chamber 11. Specifically, the controlling portion 102 controls the moving mechanism 300 to turn the substrate holding portion 200 to the processing position Q3. When a predetermined time has elapsed from the start of the processing of the substrate W with the rinse liquid in step S109, the controlling portion 102 controls the moving mechanism 300 to lower the substrate holding portion 200. Thereafter, the controlling portion 102 controls the substrate holding portion 200 such that the substrate W is held by the substrate holding portion 200. The controlling portion 102 controls the moving mechanism 300 to lift the substrate holding portion 200.

Thereafter, the controlling portion 102 controls the center robot CR and the substrate holding portion 200 to deliver the substrate W from the substrate holding portion 200 to the center robot CR. The controlling portion 102 controls the center robot CR to carry the substrate W supported by the arm of the center robot CR out of the chamber 11. In this case, the substrate holding portion 200 is retracted to a position other than the processing position Q1, and the substrate W is carried out of the chamber 11 through the second opening 12b.

As described above, the processing on the substrate W ends.

Other substrate processing methods of the second preferred embodiment are similar to those of the first preferred embodiment.

In the present preferred embodiment, as described above, the substrate holding portion 200 can perform one rotation (one turn) or more about the turning axis L200. Therefore, it is possible to suppress the occurrence of waste in the movement of the substrate holding portion 200. Specifically, the substrate holding portion 200 can reach the plurality of processing positions Q without waste, for example, by appropriately turning in the clockwise direction or the counterclockwise direction.

In addition, the substrate holding portion 200 sequentially transfers the substrates W to the plurality of processing positions Q in a predetermined turning direction (here, in the clockwise direction) about the turning axis L200. Therefore, it is possible to suppress the occurrence of waste in the movement of the substrate holding portion 200.

Other effects of the second preferred embodiment are similar to those of the first preferred embodiment.

### Third Preferred Embodiment

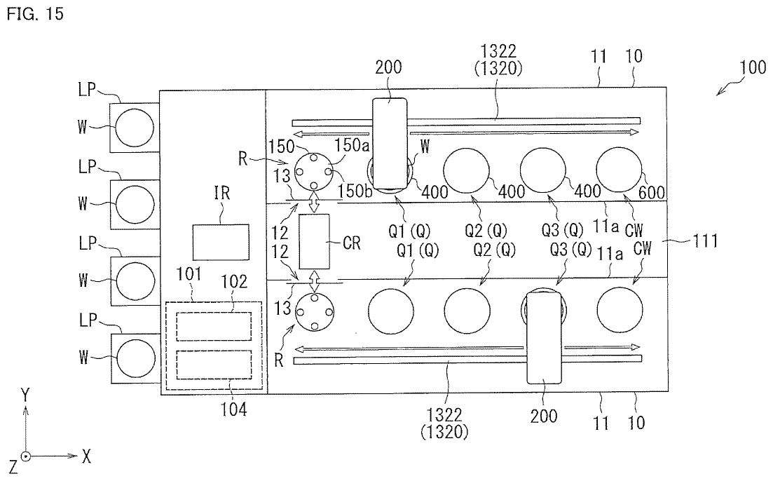

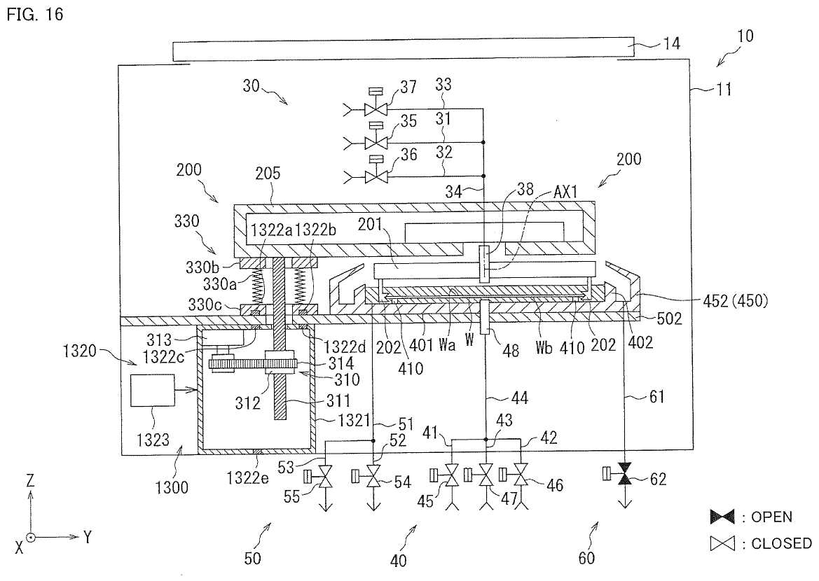

Next, a substrate processing apparatus 100 according to a third preferred embodiment of the present invention will be described with reference to FIGS. 15 and 16. FIG. 15 is a schematic plan view of a substrate processing apparatus 100 according to the third preferred embodiment. In the third preferred embodiment, unlike the first preferred embodiment and the second preferred embodiment, an example in which the substrate holding portion 200 is moved substantially linearly will be described.

As illustrated in FIG. 15, in the present preferred embodiment, the plurality of processing positions Q, the cleaning position CW, and the delivery position R are disposed on a substantially straight line in the X direction. Specifically, the plurality of processing positions Q, the cleaning position CW, and the delivery position R are disposed on a substantially straight line along a direction intersecting a direction (Y direction) in which the chamber 11 and the passage 111 are adjacent to each other. In other words, the plurality of processing positions Q, the cleaning position CW, and the delivery position R are disposed on a substantially straight line along a direction intersecting a direction (Y direction) in which the substrate W is carried into the chamber 11 from the passage 111. In the present preferred embodiment, the chamber 11 has a substantially rectangular shape extending in the X direction.

In the present preferred embodiment, for example, the delivery position R, the processing position Q1, the processing position Q2, the processing position Q3, and the cleaning position CW are disposed in order from one side in the X direction to the other side in the X direction. In the present preferred embodiment, the delivery position R is disposed at a position closest to the load port LP. Processing liquids used at the processing position Q1, the processing position Q2, and the processing position Q3 and a cleaning liquid used at the cleaning position CW are similar to those in the first preferred embodiment.

In the present preferred embodiment, one opening 12 is provided for one chamber 11. The opening 12 is defined at a position facing the delivery position R. That is, the opening 12 is defined at a position closest to the delivery position R on the side wall 11a of the chamber 11. A plurality of (for example, two) openings 12 may be provided for one chamber 11. In this case, the openings 12 may include the first opening 12a and the second opening 12b as in the second preferred embodiment.

Among the plurality of processing positions Q and the cleaning position CW, the cleaning position CW is located farthest from the opening 12.

Here, in the present preferred embodiment, the substrate processing unit 10 includes a moving mechanism 1300 (see FIG. 16) instead of the moving mechanism 300. The moving mechanism 1300 moves the substrate holding portion 200. The moving mechanism 1300 is controlled by the controlling portion 102.

In the present preferred embodiment, the moving mechanism 1300 linearly moves the substrate holding portion 200. In the present preferred embodiment, the moving mechanism 1300 moves the substrate holding portion 200 in the X direction along a rail member 1322 that will be described later. Therefore, by being linearly moved by the moving mechanism 1300, the substrate holding portion 200 can easily deliver the substrate W to and from, for example, a member at any processing position Q (here, the immersion bath 400), a member at the cleaning position CW (here, the cleaning bath 600), and a member at the delivery position R (here, the delivery table 150).

In addition, the moving mechanism 1300 moves the substrate holding portion 200 in the vertical direction as in the first preferred embodiment and the second preferred embodiment.

A detailed structure of the moving mechanism 1300 will be described later.

A substrate processing method of the third preferred embodiment is similar to that of the first preferred embodiment.

Specifically, the substrate processing method of the third preferred embodiment is similar to that of the first preferred embodiment except that the substrate holding portion 200 is turned by the moving mechanism 300 in the first preferred embodiment, and the substrate holding portion 200 is linearly moved by the moving mechanism 1300 in the third preferred embodiment. Therefore, the description of the substrate processing method of the third preferred embodiment will be omitted.

In the present preferred embodiment, as described above, the plurality of processing positions Q and the cleaning position CW are located on a straight line, and the moving mechanism 1300 moves the substrate holding portion 200 between the plurality of processing positions Q and the cleaning position CW in the chamber 11 by linearly moving the substrate holding portion 200. Therefore, the substrate holding portion 200 can be easily moved between the plurality of processing positions Q and the cleaning position CW.

As described above, out of the processing position Q and the cleaning position CW, the cleaning position CW is located farthest from the opening 12. Therefore, it is possible to suppress the processing position Q from being located farthest from the opening 12. As a result, it is possible to suppress an increase in the distance from the position where the substrate W is processed to the opening 12, so that it is possible to suppress an increase in the transfer distance of the substrate W. Therefore, it is possible to suppress an increase in time required for the processing.

Other effects of the third preferred embodiment are similar to those of the above preferred embodiment.

Next, the moving mechanism 1300 will be described with reference to FIG. 16. FIG. 16 is a schematic diagram illustrating a structure around the substrate holding portion 200 and the moving mechanism 1300 of the substrate processing apparatus 100 according to the third preferred embodiment.

The moving mechanism 1300 includes a lifting/lowering mechanism 310, a linear moving mechanism 1320 that linearly moves the substrate holding portion 200, and a shaft cover 330.

The linear moving mechanism 1320 includes a housing 1321, a rail member 1322, and a linear driving portion 1323.

In the present preferred embodiment, the rail member 1322 includes a first rail member 1322a, a second rail member 1322b, a third rail member 1322c, a fourth rail member 1322d, and a fifth rail member 1322e. In FIG. 15, the rail member 1322 is illustrated as one member for simplification of the drawing.

The first rail member 1322a and the second rail member 1322b are fixed to the upper surface of the support plate 502. The third rail member 1322c and the fourth rail member 1322d are fixed to the lower surface of the support plate 502. The fifth rail member 1322e is fixed to the floor surface of the chamber 11. In the present preferred embodiment, the rail member 1322 includes five rail members (the first rail member 1322a to the fifth rail member 1322e), but the present invention is not limited thereto, and may include at least one rail member 1322.

In the present preferred embodiment, the rail member 1322 is disposed to extend in the X direction. That is, the first rail member 1322a to the fifth rail member 1322e are disposed to be parallel to each other and extend in the X direction.

The housing 1321 has a substantially box shape. The housing 1321 is disposed below the support plate 502. The third rail member 1322c and the fourth rail member 1322d are engaged with the upper wall portion of the housing 1321. The fifth rail member 1322e is engaged with the lower wall portion of the housing 1321. Therefore, the housing 1321 is guided in the X direction by the third rail member 1322c, the fourth rail member 1322d, and the fifth rail member 1322e.

The lower plate 330c is disposed on the upper surface of the support plate 502. The lower plate 330c is engaged with the first rail member 1322a and the second rail member 1322b. Therefore, the lower plate 330c is guided in the X direction by the first rail member 1322a and the second rail member 1322b.

A through hole through which the screw shaft 311 is inserted is defined in the upper wall portion of the housing 1321. The housing 1321 accommodates a lower portion of a screw shaft 311, a nut 312, an electric motor 313, and a driving belt 314.

The through hole 502a (see FIG. 6) of the support plate 502 is defined as a long hole extending in the X direction. The lower plate 330c is formed in an annular shape having a through hole at the central portion.

The through hole of the housing 1321, the through hole 502a of the support plate 502, and the through hole of the lower plate 330c are disposed to overlap each other in the vertical direction. The screw shaft 311 is inserted into the through hole of the housing 1321, the through hole 502a of the support plate 502, and the through hole of the lower plate 330c. The first rail member 1322a and the second rail member 1322b are disposed to sandwich the through hole 502a of the support plate 502 in the Y direction in a plan view. Similarly, the third rail member 1322c and the fourth rail member 1322d are disposed to sandwich the through hole 502a of the support plate 502 in the Y direction in a plan view.

The screw shaft 311, the nut 312, the electric motor 313, and the driving belt 314 of the lifting/lowering mechanism 310 are configured in the same manner as those in the first preferred embodiment. However, the electric motor 313 is attached to the housing 1321. The electric motor 313 is attached to the inner surface of the housing 1321, for example.

The linear driving portion 1323 moves the lifting/lowering mechanism 310 in the X direction. When the linear driving portion 1323 moves the lifting/lowering mechanism 310 in the X direction, the substrate holding portion 200 is moved in the X direction. Similarly to the lifting/lowering mechanism 310, for example, the linear driving portion 1323 may include a ball screw mechanism and an electric motor that drives the ball screw mechanism.

Other structures of the third preferred embodiment are similar to those of the above preferred embodiments.

### Fourth Preferred Embodiment

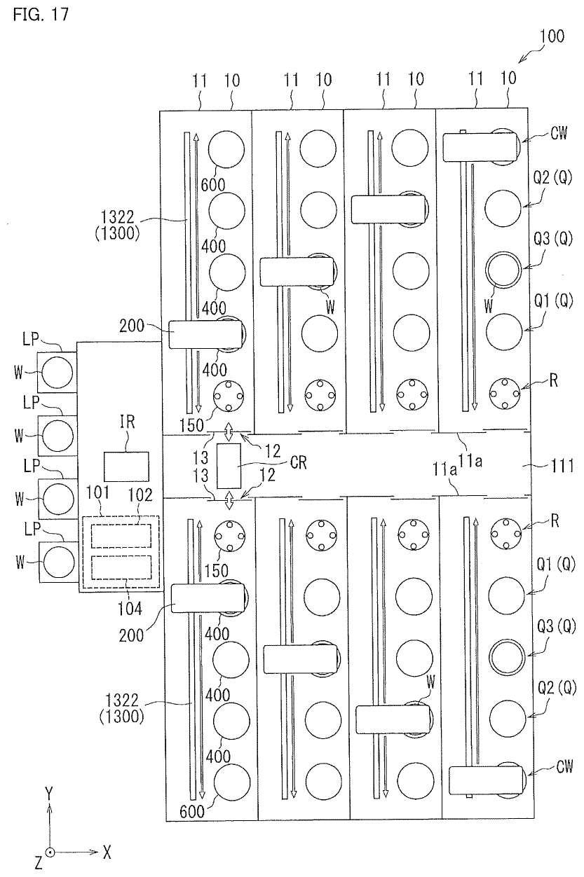

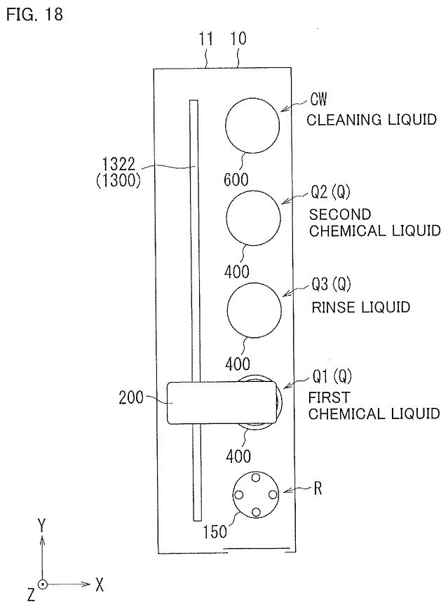

Next, a substrate processing apparatus 100 according to a fourth preferred embodiment of the present invention will be described with reference to FIGS. 17 and 18. FIG. 17 is a schematic plan view of the substrate processing apparatus 100 according to the fourth preferred embodiment. FIG. 18 is a schematic plan view illustrating the inside of one chamber 11 of the substrate processing apparatus 100 of the fourth preferred embodiment. In the fourth preferred embodiment, unlike the third preferred embodiment, an example in which the substrate holding portion 200 is moved substantially linearly in the Y direction will be described.

As illustrated in FIG. 17, in the present preferred embodiment, a plurality of (for example, four) chambers 11 are disposed on each of one side and the other side in the Y direction with respect to the passage 111. Each chamber 11 has a substantially box shape extending in the Y direction. The plurality of chambers 11 are disposed adjacent to each other in the X direction on each of one side and the other side in the Y direction with respect to the passage 111. As described above, in the present preferred embodiment, the plurality of chambers 11 extending in the Y direction are disposed side by side in the X direction.

As illustrated in FIGS. 17 and 18, in each chamber 11, a plurality of processing positions Q, a cleaning position CW, and a delivery position R are disposed on a substantially straight line in the Y direction. Specifically, the chamber 11 and the passage 111 are disposed on a substantially straight line in the direction (Y direction) in which the chamber 11 and the passage 111 are adjacent to each other. In other words, in each chamber 11, the plurality of processing positions Q, the cleaning position CW, and the delivery position R are disposed on a substantially straight line in a direction along a direction (Y direction) in which the substrate W is carried into the chamber 11 from the passage 111.

In the present preferred embodiment, the delivery position R is disposed at a position closest to the passage 111. Further, for example, the delivery position R, the processing position Q1, the processing position Q3, the processing position Q2, and the cleaning position CW are disposed in order from the passage 111 side. Processing liquids used at the processing position Q1, the processing position Q2, and the processing position Q3 and a cleaning liquid used at the cleaning position CW are similar to those in the third preferred embodiment.

In the present preferred embodiment, one opening 12 is provided for one chamber 11. The opening 12 is defined at a position facing the delivery position R.

In the present preferred embodiment, as in the third preferred embodiment, the substrate processing unit 10 includes a moving mechanism 1300 that moves the substrate holding portion 200. However, in the present preferred embodiment, the rail member 1322 is disposed to extend in the Y direction. That is, the first rail member 1322a to the fifth rail member 1322e are disposed to be parallel to each other and extend in the Y direction.

In the present preferred embodiment, the moving mechanism 1300 linearly moves the substrate holding portion 200 in the Y direction. By being linearly moved by the moving mechanism 1300, the substrate holding portion 200 can easily deliver the substrate W to and from, for example, a member at any processing position Q (here, the immersion bath 400), a member at the cleaning position CW (here, the cleaning bath 600), and a member at the delivery position R (here, the delivery table 150).

Other structures and substrate processing methods of the fourth preferred embodiment are similar to those of the third preferred embodiment.

In the present preferred embodiment, as described above, the plurality of chambers 11 extending in the Y direction are disposed side by side in the X direction. Therefore, one substrate processing apparatus 100 can process more substrates W.

Other effects of the fourth preferred embodiment are similar to those of the third preferred embodiment.

### First Modification Example

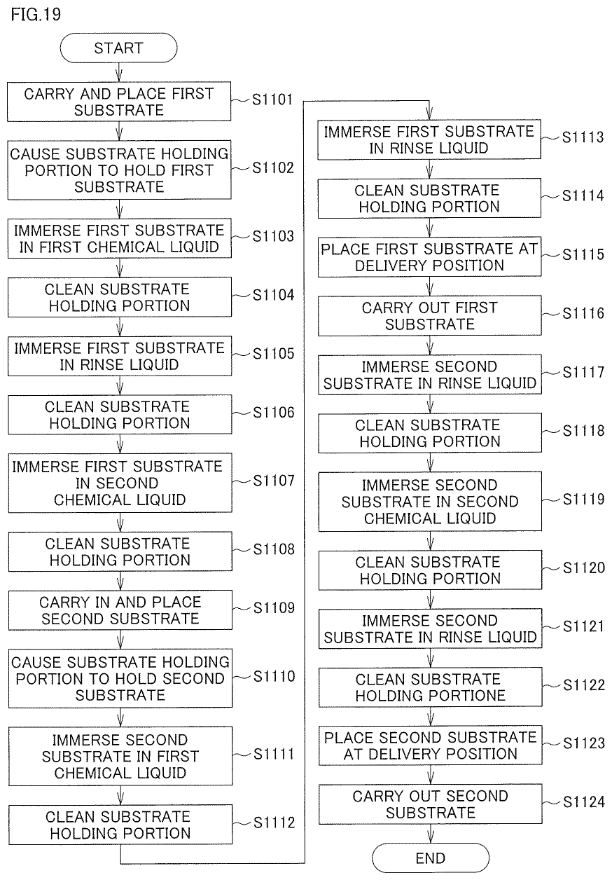

Next, a substrate processing apparatus 100 according to a first modification example of the present invention will be described with reference to FIG. 19. FIG. 19 is a flowchart illustrating a substrate processing method of the substrate processing apparatus 100 according to the first modification example of the present invention. In the first modification example, unlike the above preferred embodiments, an example in which a plurality of substrates W are processed in parallel will be described. In the following description, a portion of the first preferred embodiment will be modified, but a plurality of substrates W can be processed in parallel in other preferred embodiments. Hereinafter, for easy understanding, the plurality of substrates W may be referred to as a first substrate W1, a second substrate W2, . . . in order of being carried into the chamber 11. Note that a structure of the substrate processing apparatus 100 of the first modification example is the same as that of the first preferred embodiment.

As illustrated in FIG. 19, in step S1101, the first substrate W1 is carried into the chamber 11 in the same manner as in step S101.

Next, in step S1102, the first substrate W1 is held by the substrate holding portion 200 in the same manner as in step S102.

Next, in step S1103, the first substrate W1 is immersed in the first chemical liquid in the same manner as in step S103.

Next, in step S1104, the substrate holding portion 200 is cleaned at the cleaning position CW in the same manner as in step S104.

Next, in step S1105, the first substrate W1 is immersed in the rinse liquid in the same manner as in step S105.

Next, in step S1106, the substrate holding portion 200 is cleaned at the cleaning position CW in the same manner as in step S106.

Next, in step S1107, the first substrate W1 is immersed in the second chemical liquid in the same manner as in step S107.

Next, in step S1108, the substrate holding portion 200 is cleaned at the cleaning position CW in the same manner as in step S108.

Next, in step S1109, the second substrate W2 is carried into the chamber 11 in the same manner as in step S1101.

Next, in step S1110, the second substrate W2 is held by the substrate holding portion 200 in the same manner as in step S1102.

Next, in step S1111, the second substrate W2 is immersed in the first chemical liquid in the same manner as in step S1103.

Next, in step S1112, the substrate holding portion 200 is cleaned at the cleaning position CW in the same manner as in step S1104.

Next, in step S1113, the first substrate W1 is processed with the rinse liquid in the same manner as in step S1105.

Next, in step S1114, the substrate holding portion 200 is cleaned at the cleaning position CW in the same manner as in step S1104.

Next, in step S1115, the first substrate W1 is placed on the delivery table 150 in the same manner as in step S111.

Next, in step S1116, the first substrate W1 is carried out of the chamber 11 in the same manner as in step S112.

Next, in step S1117, the second substrate W2 is immersed in the rinse liquid in the same manner as in step S1105.

Next, in step S1118, the substrate holding portion 200 is cleaned at the cleaning position CW in the same manner as in step S1104.

Next, in step S1119, the second substrate W2 is immersed in the second chemical liquid in the same manner as in step S1107.

Next, in step S1120, the substrate holding portion 200 is cleaned at the cleaning position CW in the same manner as in step S1104.

Next, in step S1121, the second substrate W2 is processed with the rinse liquid in the same manner as in step S1117.

Next, in step S1122, the substrate holding portion 200 is cleaned at the cleaning position CW in the same manner as in step S1104.

Next, in step S1123, the second substrate W2 is placed on the delivery table 150 in the same manner as in step S1115.

Next, in step S1124, the second substrate W2 is carried out of the chamber 11 in the same manner as in step S1116.

As described above, the processing on the first substrate W1 and the second substrate W2 ends.

Other processing flows of the first modification example are similar to those of the first preferred embodiment.

In the first modification example, as described above, the substrate holding portion 200 transfers the substrates W to the plurality of processing positions Q to process the plurality of substrates W in parallel. Therefore, the processing time of the plurality of substrates W can be shortened.

In addition, the chuck pins 202 are cleaned at the cleaning position CW when the substrate W is held again. Specifically, for example, after releasing the holding of the first substrate W1, the chuck pins 202 are cleaned at the cleaning position CW before holding the second substrate W2. Therefore, for example, since it is possible to suppress particles of the first substrate W1 from adhering to the second substrate W2 through the chuck pins 202, it is possible to suppress contamination of the second substrate W2.

Other effects of the first modification example are similar to those of the first preferred embodiment.

### Second Modification Example

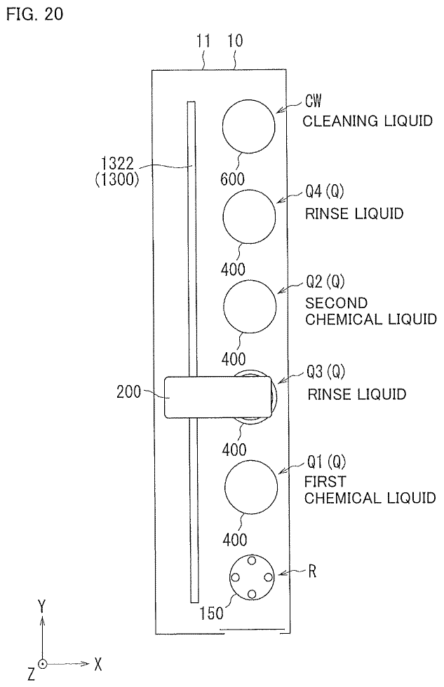

Next, a substrate processing apparatus 100 according to a second modification example of the present invention will be described with reference to FIG. 20. FIG. 20 is a schematic plan view illustrating the inside of one chamber 11 of the substrate processing apparatus 100 according to the second modification example of the present invention. In the second modification example, unlike the above-described preferred embodiments and modification examples, an example will be described in which the same number of processing positions Q at which processing using a rinse liquid is performed as the number of processing positions Q at which processing using a chemical liquid is performed are provided. In the following description, a portion of the fourth preferred embodiment will be modified, but the second modification example is applicable to other preferred embodiments and modification examples.

In the second modification example, the processing positions Q include a processing position Q1, a processing position Q2, a processing position Q3, and a processing position Q4. In the second modification example, the substrate W is processed by using the first chemical liquid at the processing position Q1. At the processing position Q2, the substrate W is processed by using the second chemical liquid. At the processing position Q3 and the processing position Q4, the substrate W is processed by using the rinse liquid.

In the second modification example, the delivery position R, the processing position Q1, the processing position Q3, the processing position Q2, the processing position Q4, and the cleaning position CW are disposed in order from the passage 111 side. The substrate holding portion 200 transfers the substrates W from the delivery position R in the order of the processing position Q1, the processing position Q3, the processing position Q2, and the processing position Q4. That is, the plurality of processing positions Q (the processing position Q1, the processing position Q3, the processing position Q2, and the processing position Q4) are disposed in the order in which the substrates W are transferred.

Other structures of the second modification example are similar to those of the fourth preferred embodiment.

In the second modification example, as described above, the processing position Q3 at which the substrate W processed at the processing position Q1 is rinsed and the processing position Q4 at which the substrate W processed at the processing position Q2 is rinsed are provided. In other words, the number of processing positions (here, the processing position Q3 and the processing position Q4) using the rinse liquid is the same as the number of processing positions (here, the processing position Q1 and the processing position Q2) using the chemical liquid. Therefore, for example, in a case where the substrate W is immersed in the rinse liquid, it is possible to suppress mixing of a plurality of chemical liquids with the rinse liquid. In addition, for example, unlike a case where only one processing position Q at which the substrate W is processed with the rinse liquid is provided (the first to fourth preferred embodiments, etc.), even if the timings to perform the rinse processing overlap when the plurality of substrates W are processed in parallel, it is possible to suppress the occurrence of the standby time.

Other effects of the second modification example are similar to those of the fourth preferred embodiment.

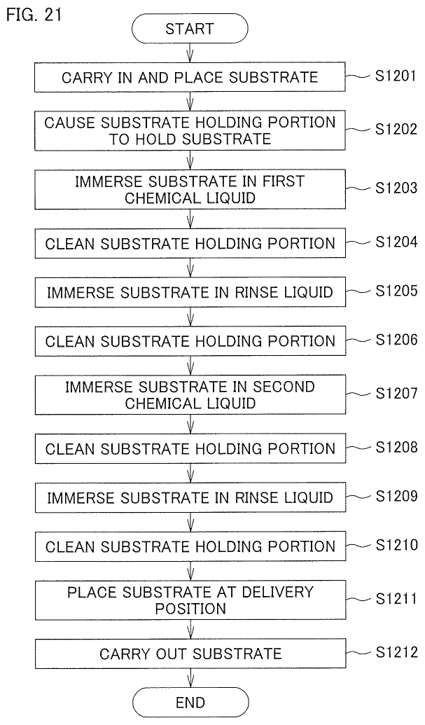

Next, a substrate processing method according to the second modification example will be described with reference to FIG. 21. FIG. 21 is a flowchart illustrating a substrate processing method of the substrate processing apparatus 100 according to the second modification example.

As illustrated in FIG. 21, in step S1201, the substrate W is carried into the chamber 11 in the same manner as in step S101.

Next, in step S1202, the substrate W is held by the substrate holding portion 200. Specifically, the controlling portion 102 controls the moving mechanism 1300 to move the substrate holding portion 200 to the delivery position R. The controlling portion 102 controls the moving mechanism 1300 and the substrate holding portion 200 such that the substrate W is held by the substrate holding portion 200.

Next, in step S1203, the substrate W is processed with the first chemical liquid. Specifically, the controlling portion 102 controls the moving mechanism 1300 to move the substrate holding portion 200 to the processing position Q1. The controlling portion 102 controls the moving mechanism 1300 to lower the substrate holding portion 200.

Next, in step S1204, the substrate holding portion 200 is cleaned at the cleaning position CW. Specifically, the controlling portion 102 controls the moving mechanism 1300 to move the substrate holding portion 200 to the cleaning position CW.

The controlling portion 102 controls the moving mechanism 1300 to lower the substrate holding portion 200. As a result, the tip portion (lower portion) of the chuck pin 202 of the substrate holding portion 200 is immersed in the cleaning liquid stored in advance in the cleaning bath 600.

Next, in step S1205, the substrate W is processed with the rinse liquid. Specifically, the controlling portion 102 controls the moving mechanism 1300 to move the substrate holding portion 200 to the processing position Q1. When a predetermined time has elapsed from the start of the processing of the substrate W with the first chemical liquid in step S1203, the controlling portion 102 controls the moving mechanism 1300 and the substrate holding portion 200 to lower the substrate holding portion 200 such that the substrate W is held by the substrate holding portion 200. Thereafter, the controlling portion 102 controls the moving mechanism 1300 to lift the substrate holding portion 200 and move the substrate holding portion 200 to the processing position Q3.

The controlling portion 102 controls the moving mechanism 1300 to lower the substrate holding portion 200. As a result, the substrate W is immersed in the rinse liquid stored in advance in the immersion bath 400.

Next, in step S1206, the substrate holding portion 200 is cleaned at the cleaning position CW in the same manner as in step S1204.

Next, in step S1207, the substrate W is processed with the second chemical liquid. Specifically, the controlling portion 102 controls the moving mechanism 1300 to move the substrate holding portion 200 to the processing position Q3. When a predetermined time has elapsed from the start of the processing of the substrate W with the rinse liquid in step S1205, the controlling portion 102 controls the moving mechanism 1300 and the substrate holding portion 200 to lower the substrate holding portion 200 such that the substrate W is held by the substrate holding portion 200. Thereafter, the controlling portion 102 controls the moving mechanism 1300 to lift the substrate holding portion 200 and move the substrate holding portion 200 to the processing position Q2.

The controlling portion 102 controls the moving mechanism 1300 to lower the substrate holding portion 200. As a result, the substrate W is immersed in the second chemical liquid stored in advance in the immersion bath 400.

Next, in step S1208, the substrate holding portion 200 is cleaned at the cleaning position CW in the same manner as in step S1204.

Next, in step S1209, the substrate W is processed with the rinse liquid. In this case, in the second modification example, unlike the above-described preferred embodiments and modification examples, the substrate W is rinsed at the processing position Q (here, the processing position Q4) different from the processing position Q (here, the processing position Q3) at which the rinse processing is performed after the processing using the first chemical liquid.

Specifically, the controlling portion 102 controls the moving mechanism 1300 to move the substrate holding portion 200 to the processing position Q2. When a predetermined time has elapsed from the start of the processing of the substrate W with the second chemical liquid in step S1207, the controlling portion 102 controls the moving mechanism 1300 and the substrate holding portion 200 to lower the substrate holding portion 200 such that the substrate W is held by the substrate holding portion 200. Thereafter, the controlling portion 102 controls the moving mechanism 1300 to lift the substrate holding portion 200 and move the substrate holding portion 200 to the processing position Q4.

The controlling portion 102 controls the moving mechanism 1300 to lower the substrate holding portion 200. As a result, the substrate W is immersed in the rinse liquid stored in advance in the immersion bath 400.

Next, in step S1210, the substrate holding portion 200 is cleaned at the cleaning position CW in the same manner as in step S1204.

Next, in step S1211, the substrate W is placed on the delivery table 150. Specifically, the controlling portion 102 controls the moving mechanism 1300 to move the substrate holding portion 200 to the delivery position R. The controlling portion 102 controls the moving mechanism 1300 and the substrate holding portion 200 to lower the substrate holding portion 200 and place the substrate W on the delivery table 150. Thereafter, the controlling portion 102 controls the moving mechanism 1300 to retract the substrate holding portion 200 from the delivery position R.

Next, in step S1212, the substrate W is carried out of the chamber 11 in the same manner as in step S112.

As described above, the processing on the substrate W ends.

Other substrate processing methods of the second modification example are similar to those of the fourth preferred embodiment.

### Third Modification Example

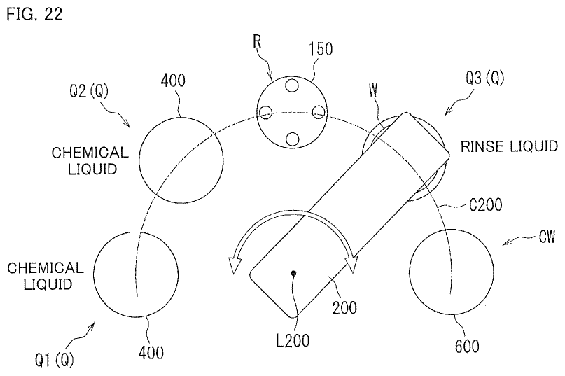

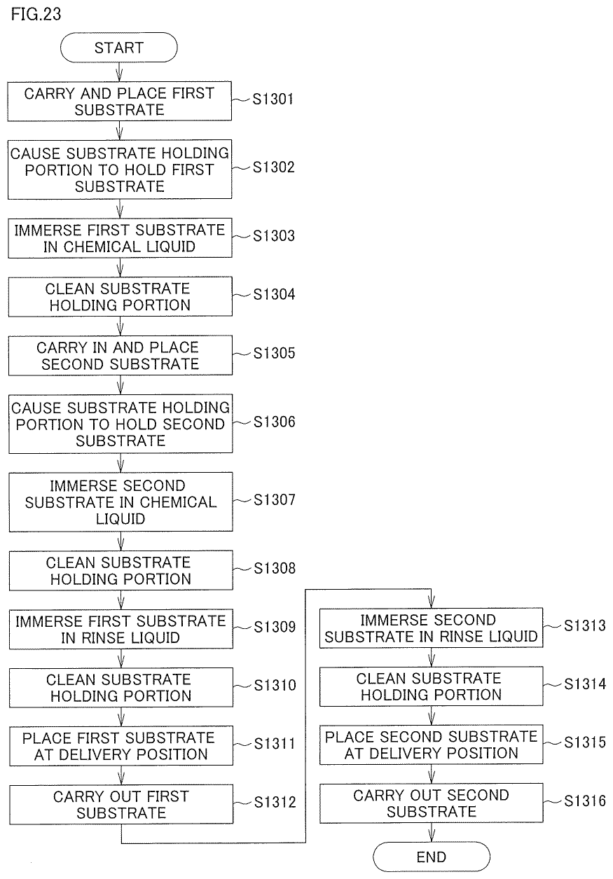

Next, a substrate processing apparatus 100 according to a third modification example of the present invention will be described with reference to FIGS. 22 and 23. FIG. 22 is a schematic plan view illustrating the inside of one chamber 11 of the substrate processing apparatus 100 of the third modification example. In the third modification example, unlike the above preferred embodiments and modification examples, an example in which a plurality of substrates W are processed in parallel by using the same chemical liquid will be described. Hereinafter, a portion of the first preferred embodiment will be modified, but in other preferred embodiments, a plurality of substrates W can be processed in parallel by using the same chemical liquid.

As illustrated in FIG. 22, in the substrate processing apparatus 100 of the third modification example, the chemical liquid stored in the immersion bath 400 at the processing position Q1 and the chemical liquid stored in the immersion bath 400 at the processing position Q2 are the same chemical liquid.

Other configurations of the third modification example are similar to those of the first preferred embodiment.

Next, a substrate processing method performed by the substrate processing apparatus 100 according to the third modification example will be described with reference to FIG. 23. FIG. 23 is a flowchart illustrating a substrate processing method of the substrate processing apparatus 100 according to the third modification example of the present invention.

As illustrated in FIG. 23, in step S1301, the first substrate W1 is carried into the chamber 11 in the same manner as in step S101.

Next, in step S1302, the first substrate W1 is held by the substrate holding portion 200 in the same manner as in step S102.

Next, in step S1303, the first substrate W1 is immersed in the chemical liquid in the same manner as in step S103. In this case, the first substrate W1 is immersed at the processing position Q1, for example.

Next, in step S1304, the substrate holding portion 200 is cleaned at the cleaning position CW in the same manner as in step S104.

Next, in step S1305, the second substrate W2 is carried into the chamber 11 in the same manner as in step S1301.

Next, in step S1306, the second substrate W2 is held by the substrate holding portion 200 in the same manner as in step S1302.

Next, in step S1307, the second substrate W2 is immersed in the chemical liquid in the same manner as in step S1303. In this case, the second substrate W2 is immersed at the processing position Q2, for example.

Next, in step S1308, the substrate holding portion 200 is cleaned at the cleaning position CW in the same manner as in step S1304.

Next, in step S1309, the first substrate W1 is immersed in the rinse liquid in the same manner as in step S105.

Next, in step S1310, the substrate holding portion 200 is cleaned at the cleaning position CW in the same manner as in step S1304.

Next, in step S1311, the first substrate W1 is placed on the delivery table 150 in the same manner as in step S111.

Next, in step S1312, the first substrate W1 is carried out of the chamber 11 in the same manner as in step S112.

Next, in step S1313, the second substrate W2 is immersed in the rinse liquid in the same manner as in step S1309.

Next, in step S1314, the substrate holding portion 200 is cleaned at the cleaning position CW in the same manner as in step S1304.

Next, in step S1315, the second substrate W2 is placed on the delivery table 150 in the same manner as in step S1311.

Next, in step S1316, the second substrate W2 is carried out of the chamber 11 in the same manner as in step S1312.

As described above, the processing on the first substrate W1 and the second substrate W2 ends.

Other processing flows of the third modification example are similar to those of the first preferred embodiment.

Note that after step S1311 (after the holding of the first substrate W1 by the substrate holding portion 200 is released) and before step S1313 (before the second substrate W2 is held by the substrate holding portion 200), the substrate holding portion 200 may be cleaned at the cleaning position CW.

In the third modification example, as described above, the plurality of processing positions Q include at least two processing positions Q (here, the processing position Q1 and the processing position Q2) at which the substrates W are processed with the same chemical liquid. Therefore, for example, the same processing can be performed on at least two (here, two) substrates W in parallel.

Other effects of the third modification example are similar to those of the first preferred embodiment.

### Fourth Modification Example

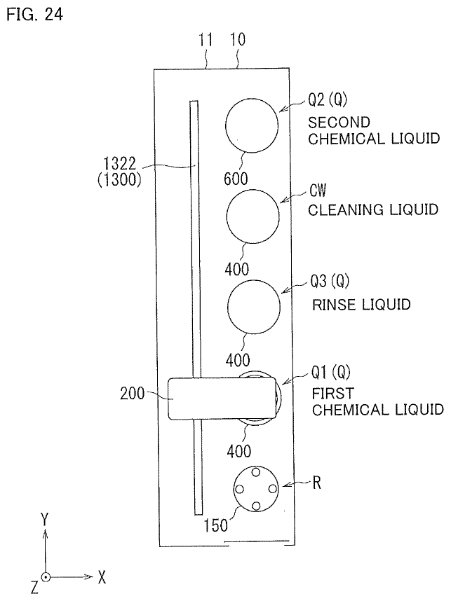

Next, a substrate processing apparatus 100 according to a fourth modification example of the present invention will be described with reference to FIG. 24. FIG. 24 is a schematic plan view illustrating the inside of one chamber 11 of the substrate processing apparatus 100 according to the fourth modification example of the present invention. In the fourth modification example, an example in which the cleaning position CW is located at a position different from that in the above preferred embodiments and modification examples will be described. In the following description, a portion of the fourth preferred embodiment will be modified, but the fourth modification example is applicable to other preferred embodiments and modification examples.

In the fourth modification example, for example, as in the fourth preferred embodiment, the processing positions Q include a processing position Q1, a processing position Q2, and a processing position Q3. In the fourth modification example, the cleaning position CW is located between the processing positions Q. In the fourth modification example, the cleaning position CW is located adjacent to the position (processing position Q3) at which the rinse processing is performed. Specifically, in the fourth modification example, the delivery position R, the processing position Q1, the processing position Q3, the cleaning position CW, and the processing position Q2 are disposed in order from the passage 111 side. In the fourth modification example, the processing position Q1 and the processing position Q2 are examples of a “chemical liquid processing position” of the present invention. The processing position Q3 is an example of a “rinse processing position” of the present invention.

Other structures and substrate processing methods of the fourth modification example are similar to those of the fourth preferred embodiment.

In the fourth modification example, as described above, the cleaning position CW is located between the processing positions Q. Therefore, for example, compared with the case where the cleaning position CW is not located between the processing positions Q as in the fourth preferred embodiment, etc., a total distance between the cleaning position CW and the plurality of processing positions Q can be reduced. That is, a moving distance of the substrate holding portion 200 can be reduced. Therefore, the time required for the movement of the substrate holding portion 200 can be shortened.

As described above, the cleaning position CW is located adjacent to the rinse processing position (here, the processing position Q3) at which the substrate W is processed with the rinse liquid. Therefore, the distance from the rinse processing position to the cleaning position CW can be shortened. Since the time for the rinse processing is shorter than that for the chemical liquid processing, the time required to clean the substrate holding portion 200 during the rinse processing is preferably shorter. Therefore, it is effective to shorten the time required for movement of the substrate holding portion 200 between the rinse processing position and the cleaning position CW by shortening the distance from the rinse processing position to the cleaning position CW.

The preferred embodiments and the modification examples of the present invention have been described above with reference to the drawings. However, the present invention is not limited to the above preferred embodiments and modification examples, and can be implemented in various aspects without departing from the concept thereof. In addition, various inventions can be achieved by appropriately combining a of plurality 41 constituents disclosed in the above preferred embodiments and modification examples. For example, some constituents may be deleted from all the constituents described in the preferred embodiments. Furthermore, the constituents of different preferred embodiments and modification examples may be combined as appropriate. The drawings mainly illustrate the respective constituents schematically for ease of understanding and there are cases where thicknesses, lengths, numbers, intervals, etc., of the respective constituents illustrated differ from actual ones due to convenience of drawing preparation. In addition, the materials, the shapes, the dimensions, etc., of the respective constituents described in the above preferred embodiments and modification examples are merely examples, and are not particularly limited, and various modification examples can be made without substantially departing from the effects of the present invention.

For example, in the preferred embodiments and the modification examples (hereinafter, referred to as the preferred embodiments, etc., in some cases), an example in which the chuck pin 202 is immersed in the rinse liquid stored in the cleaning bath 600 to clean the chuck pin 202 has been described, but the present invention is not limited thereto. For example, a spray nozzle that blows out a cleaning liquid may be provided at the cleaning position CW. The chuck pin 202 may be cleaned by spraying a rinse liquid to the chuck pin 202 by using the spray nozzle.

In the above preferred embodiments, etc., an example in which the chuck pin 202 is used as the contact member in contact with the substrate W has been described, but the present invention is not limited thereto. The contact member may have a shape other than the pin shape, for example. Furthermore, the contact member may be, for example, a member that suctions and holds the substrate W.

In the above preferred embodiments, etc., an example in which one type of processing is performed on the substrate W at one processing position Q has been described, but the present invention is not limited thereto. For example, a plurality of types of processing may be performed on the substrate W at one processing position Q. Specifically, for example, at one processing position Q, the substrate W may be processed with a chemical liquid, and then rinsed with a rinse liquid.

Further, for example, an example in which the delivery table 150 is provided in the chamber 11 in the first preferred embodiment, the third preferred embodiment, and the fourth preferred embodiment, and the delivery table 150 is not provided in the chamber 11 in the second preferred embodiment has been described, but the present invention is not limited thereto. For example, in the first preferred embodiment, the third preferred embodiment, and the fourth preferred embodiment, the delivery table 150 need not be provided in the chamber 11. Also, in the second preferred embodiment, the delivery table 150 may be provided in the chamber 11.

In addition, for example, in the above preferred embodiments, an example in which the substrate W is processed by using the first chemical liquid and the second chemical liquid has been described, but the present invention is not limited thereto. For example, as in the third modification example, the substrate W may be processed by using only one chemical liquid. In addition, the substrate W may be processed by using three or more chemical liquids.

In the above preferred embodiment, etc., an example in which the substrate W is placed on the support table 410 when the substrate W is immersed in the processing liquid has been described, but the present invention is not limited thereto. For example, when the substrate W is immersed in the processing liquid stored in the immersion bath 400, the substrate W may be immersed for predetermined time in a state in which the substrate W is held by the substrate holding portion 200. In this case, the support table 410 need not be provided in the immersion bath 400. In this case, the substrate W may be immersed while the substrate W is being rotated by the substrate holding portion 200. With this configuration, since the substrate W can be immersed in a state in which the processing liquid is convected, the substrate W can be processed more uniformly.

In the above preferred embodiment, etc., an example in which the substrate W is immersed in the processing liquid when the substrate W is processed with the processing liquid has been described, but the present invention is not limited thereto. For example, the substrate may be processed by ejecting the processing liquid onto the substrate W without providing the immersion bath 400 storing the processing liquid. In particular, since the processing time using the rinse liquid is shorter than the processing time using the chemical liquid, the substrate W may be rinsed by continuously ejecting the rinse liquid to the substrate W without providing the immersion bath 400 storing the rinse liquid.

In addition, for example, in the third preferred embodiment, an example has been described in which only one opening 12 is provided for one chamber 11, and the substrate W is carried into the chamber 11 or carried out of the chamber 11 through one (the same) opening 12, but the present invention is not limited thereto. For example, in the configuration of the third preferred embodiment, as in the second preferred embodiment, one chamber 11 may be provided with the first opening 12a through which the substrate W is carried into the chamber 11 and the second opening 12b through which the substrate W is carried out of the chamber 11. Further, for example, in the configuration of the second preferred embodiment, only one opening 12 may be provided for one chamber 11.

In addition, in the above preferred embodiments, etc., an example has been described in which the moving mechanisms 300 and 1300 immerse the substrate W in the processing liquid by moving the substrate holding portion 200 in a state in which the processing liquid is stored in the immersion bath 400, but the present invention is not limited thereto. For example, the substrate W may be disposed in the immersion bath 400 in a state in which the processing liquid is not stored, and then the processing liquid may be supplied into the immersion bath 400 by ejecting the processing liquid from the nozzle 38 and the nozzle 48, and the processing liquid may be stored in the immersion bath 400.

In the above preferred embodiments, etc., an example in which the substrate W is rotated when the substrate W is immersed in the processing liquid stored in advance has been described, but the present invention is not limited thereto, and the substrate W need not be rotated.

In the above preferred embodiments, etc., an example in which the step of drying the substrate W and the substrate holding portion 200 is not provided has been described, but the present invention is not limited thereto. In the above preferred embodiments, etc., the substrate W and/or the substrate holding portion 200 may be dried.

In addition, in the above preferred embodiments, etc., an example in which the first chemical liquid, the second chemical liquid, and the rinse liquid are ejected from the same nozzle (for example, the nozzle 38 and the nozzle 48) has been described, but the present invention is not limited thereto. For example, a nozzle that ejects the first chemical liquid, a nozzle that ejects the second chemical liquid, and a nozzle that ejects the rinse liquid may be separately provided.

In the above preferred embodiments, etc., an example in which the lifting/lowering mechanism 310 moves the substrate holding portion 200 in the up-down direction has been described, but the present invention is not limited thereto. For example, the lifting/lowering mechanism 310 may move the immersion bath 400 in the up-down direction. That is, the lifting/lowering mechanism 310 may relatively move the substrate holding portion 200 and the immersion bath 400 in the up-down direction. At that time, the lifting/lowering mechanism 310 may move one of the substrate holding portion 200 and the immersion bath 400, or may move both of the substrate holding portion 200 and the immersion bath 400.

Unlike the above preferred embodiments, etc., for example, one chamber 11 may be provided with a processing position Q at which only the first substrate W1 is processed with the first chemical liquid and a processing position Q at which only the second substrate W2 is processed with the second chemical liquid. In other words, a plurality of substrates W that are subjected to different types of processing may be processed in parallel.

In addition, in the above preferred embodiments, etc., an example in which the substrate W is processed in a state in which the substrate W is horizontal has been described, but the present invention is not limited thereto. For example, the substrate W may be processed in a state in which the substrate W is made vertical or oblique.

The present invention is suitably used for a substrate processing apparatus.

What is claimed is:

1. A substrate processing apparatus comprising:
a chamber that accommodates a substrate;
a substrate holding portion that is disposed in the chamber and holds the substrates one by one; and
a moving mechanism that moves the substrate holding portion, wherein
the substrate holding portion includes a contact member that comes into contact with the substrate, and
the moving mechanism moves the substrate holding portion within the chamber between at least one processing position at which the substrate is processed with a processing liquid and a cleaning position at which the contact member is cleaned.

2. The substrate processing apparatus according to claim 1, comprising an immersion bath that is disposed at the processing position, stores the processing liquid, accommodates the substrate, and immerses the substrate in the processing liquid.

3. The substrate processing apparatus according to claim 2, wherein the immersion bath is provided with a support table that supports the substrate.

4. The substrate processing apparatus according to claim 1, further comprising a cleaning bath that is disposed at the cleaning position, stores a cleaning liquid, accommodates the contact member, and immerses the contact member in the cleaning liquid.

5. The substrate processing apparatus according to claim 4, wherein
the substrate holding portion includes a rotation driving portion that rotates the contact member, and
the rotation driving portion rotates the contact member in a state in which the contact member is immersed in the cleaning liquid stored in the cleaning bath.

6. The substrate processing apparatus according to claim 1, wherein
a plurality of the processing positions are provided, and
the moving mechanism moves the substrate holding portion between the plurality of processing positions.

7. The substrate processing apparatus according to claim 6, wherein
the plurality of processing positions include a first processing position and a second processing position,
the substrate is processed with a first processing liquid at the first processing position, and
the substrate is processed with a second processing liquid different from the first processing liquid at the second processing position.

8. The substrate processing apparatus according to claim 7, wherein
the plurality of processing positions further include a third processing position,
the processing liquid includes a first chemical liquid that is the first processing liquid, a second chemical liquid that is the second processing liquid, and a rinse liquid,
the substrate is processed with the first chemical liquid at the first processing position,
the substrate is processed with the second chemical liquid at the second processing position, and
the substrate is processed with the rinse liquid at the third processing position.

9. The substrate processing apparatus according to claim 7, wherein
the processing liquid includes a first chemical liquid that is the first processing liquid and a second chemical liquid that is the second processing liquid, and
the contact member is cleaned at the cleaning position after coming into contact with one of the first chemical liquid and the second chemical liquid and before coming into contact with the other of the first chemical liquid and the second chemical liquid.

10. The substrate processing apparatus according to claim 6, wherein
the substrate holding portion transfers a plurality of the substrates one by one to the plurality of processing positions to process the plurality of substrates in parallel, and
the contact member is cleaned at the cleaning position before holding the substrate again.

11. The substrate processing apparatus according to claim 1, further comprising:
a supporting member that is disposed inside the chamber and supports the substrate, wherein
the chamber has an opening through which an inside and an outside of the chamber communicate with each other and the substrate is carried in and/or out,
the inside of the chamber includes a support position at which the supporting member is disposed,
the support position is located closer to the opening than the processing position, and
the substrate holding portion transfers the substrate from the support position to the processing position.

12. The substrate processing apparatus according to claim 1, wherein
the substrate holding portion horizontally holds the substrate,
the substrate holding portion includes a base disposed above the substrate and a plurality of chuck pins protruding downward from the base and holding a circumferential edge of the substrate, and
the plurality of chuck pins are the contact member.

13. The substrate processing apparatus according to claim 1, wherein
the moving mechanism includes a turning mechanism that turns the substrate holding portion about a turning axis,
the processing position and the cleaning position are located on a circle centered on the turning axis, and
the turning mechanism moves the substrate holding portion between the processing position and the cleaning position in the chamber.

14. The substrate processing apparatus according to claim 13, wherein
the chamber has an opening through which an inside and an outside of the chamber communicate with each other and the substrate is carried in and/or out, and
the cleaning position is farther from the opening than the processing position.

15. The substrate processing apparatus according to claim 1, wherein
a plurality of the processing positions are provided,
the plurality of processing positions and the cleaning position are located on a straight line, and
the moving mechanism moves the substrate holding portion within the chamber between the plurality of processing positions and the cleaning position by linearly moving the substrate holding portion.

16. The substrate processing apparatus according to claim 15, wherein
the chamber has an opening through which an inside and an outside of the chamber communicate with each other and the substrate is carried in and/or out, and
the cleaning position is farther from the opening than the processing position.

17. The substrate processing apparatus according to claim 1, wherein
a plurality of the processing positions are provided, and
the cleaning position is located between two of the processing positions.

18. The substrate processing apparatus according to claim 1, wherein
a plurality of the processing positions are provided,
the processing liquid includes a chemical liquid and a rinse liquid,
the plurality of processing positions include
a chemical liquid processing position at which the substrate is processed with the chemical liquid, and
a rinse processing position at which the substrate is processed with the rinse liquid, and
the cleaning position is adjacent to the rinse processing position.
